(19) United States
(12) Patent Application Publication
(10) Pub. No.: US 2024/0420969 A1
(43) Pub. Date: Dec. 19, 2024

(54) VALVE MANIFOLD FOR SEMICONDUCTOR PROCESSING

(71) Applicant: Lam Research Corporation, Fremont, CA (US)

(72) Inventors: Aaron Blake Miller, West Linn, OR (US); Gopinath Bhimarasetti, Portland, OR (US)

(73) Assignee: Lam Research Corporation, Fremont, CA (US)

(21) Appl. No.: 18/701,439

(22) PCT Filed: Oct. 18, 2022
(86) PCT No.: PCT/US2022/078262

§ 371 Date: Apr. 15, 2024

Related U.S. Application Data
(60) Provisional application No. 63/262,736, filed on Oct. 19, 2021.

(51) Int. Cl. H01L 21/67

(52) U.S. Cl. CPC H01L 21/67017

(57) ABSTRACT

A valve manifold for use in a semiconductor processing tool comprises a manifold body, a purge gas inlet, a process gas inlet, a manifold outlet, a divert outlet, a first valve interface, a second valve interface, and a third valve interface. The first valve interface and the third valve interface each includes a first port, and a second port. The second valve interface includes a first port, a second port, a third port, and a fourth port.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### BACKGROUND

During semiconductor processing operations, a substrate is typically supported on a pedestal within a processing chamber and process gases are flowed into the chamber in order to deposit one or more layers of material onto the substrate, or to remove one or more layers of material from a substrate. The commercial viability of a semiconductor processing operation depends in large part upon within-wafer uniformity and wafer-to-wafer repeatability of the process conditions. Apparatuses for controlling the gas flows are required to create desired processing conditions and the desired overall process and product.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1 depicts an off-angle view of a valve manifold according to disclosed embodiments.

FIG. 2 depicts a top view of valve manifold of FIG. 1.

FIG. 3 depicts the off-angle view of the valve manifold of FIG. 1 and various internal features of the valve manifold.

FIG. 4 depicts an off-angle view of the internal flowpath volumes of the valve manifold of FIG. 3.

FIG. 5 depicts an off-angle view of an apparatus that includes the valve manifold of FIG. 1 and a plurality of valves interfaced with the valve manifold.

FIG. 6 depicts an exploded view of the apparatus of FIG. 5.

FIG. 7A depicts the apparatus's valve manifold flowpaths and valve interfaces of FIG. 4 and various gas flows according to disclosed embodiments.

FIG. 7B depicts the apparatus's valve manifold flowpaths and valve interfaces of FIG. 4 and alternate gas flows according to disclosed embodiments.

FIG. 7C depicts the apparatus's valve manifold flowpaths and valve interfaces of FIG. 4 and various gas flows according to disclosed embodiments.

FIG. 8A depicts a valve operation and timing diagram according to disclosed embodiments.

FIG. 8B depicts an alternate valve operation and timing diagram.

FIG. 9 depicts a first example technique according to disclosed embodiments.

FIG. 10 depicts a flowchart of an example sequence of operations for forming a film of material on a substrate via an atomic layer deposition process.

FIG. 11 depicts a flowchart of an example sequence of operations for etching a layer of material from a wafer via an atomic layer etching process.

FIG. 12 schematically shows an embodiment of a process station that may be used to deposit material.

FIG. 13 depicts an example multi-station substrate processing apparatus.

FIG. 14 schematically shows a cross-sectional view of an inductively coupled plasma etching apparatus 1400 in accordance with certain embodiments herein.

FIG. 15 depicts another substrate processing apparatus.

### DETAILED DESCRIPTION

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the invention is implemented for use with such a wafer. However, the invention is not so limited. The work piece may be of various shapes, sizes, and materials. In addition to semiconductor wafers, other work pieces that may take advantage of this invention include various articles such as printed circuit boards, magnetic recording media, magnetic recording sensors, mirrors, optical elements, micro-mechanical devices and the like.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

### Introduction and Context

Some semiconductor processes are used to deposit one or more layers of a material onto a substrate. Example deposition processes include chemical vapor deposition (“CVD”), plasma-enhanced CVD (“PECVD”), atomic layer deposition (“ALD”), low pressure CVD, ultra-high CVD, physical vapor deposition (“PVD”), and conformal film deposition (“CFD”). Some CVD processes may deposit a film on a wafer surface by flowing one or more gas reactants into a reactor which form film precursors and by-products. The precursors are transported to the wafer surface where they are adsorbed by the wafer, diffused into the wafer, and deposited on the wafer by chemical reactions, including by the generation of a plasma in PECVD. Some other deposition processes involve multiple film deposition cycles, each producing a “discrete” film thickness. ALD is one such film deposition method, but any technique which puts down thin layers of film and used in a repeating sequential matter may be viewed as involving multiple cycles of deposition.

As device and features size continue to shrink in the semiconductor industry, and also as 3D devices structures become more prevalent in integrated circuit (IC) design, the capability of depositing thin conformal films (films of material having a uniform thickness relative to the shape of the underlying structure, even if non-planar) continues to gain importance. ALD is a film forming technique which is well-suited to the deposition of conformal films due to the fact that a single cycle of ALD only deposits a single thin layer of material, the thickness being limited by the amount of one or more film precursor reactants which may adsorb onto the substrate surface (i.e., forming an adsorption-limited layer) prior to the film-forming chemical reaction itself. Multiple “ALD cycles” may then be used to build up a film of the desired thickness, and since each layer is thin and conformal, the resulting film substantially conforms to the shape of the underlying devices structure. In certain embodiments, each ALD cycle includes the following steps: (1) Exposure of the substrate surface to a first precursor, i.e., a “dose phase,” (2) purge of the reaction chamber in which the substrate is located, i.e., a purge phase,” (3) activation of a reaction of the substrate surface, typically with a plasma and/or a second precursor, i.e., an “activation phase,” and (4) purge of the reaction chamber in which the substrate is located, i.e., another purge phase

The duration of each ALD cycle may typically be less than 25 seconds or less than 10 seconds or less than 5 seconds. The plasma exposure step (or steps) of the ALD cycle may be of a short duration, such as a duration of 1 second or less, for example. The plasma may be of other durations longer than that 1 second, such as 2 seconds, 5 seconds, or 10 seconds, for instance.

Some semiconductor fabrication processes involve patterning and etching of various materials, including conductors, semiconductors, and dielectrics. Some examples include conductors, such as metals or carbon; semiconductors, such as silicon or germanium; and dielectrics, such as silicon oxide, aluminum dioxide, zirconium dioxide, hafnium dioxide, silicon nitride, and titanium nitride. Atomic layer etching (“ALE”) processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts. Generally, a cycle contains one instance of a unique sequence of operations.

As an example, a conventional ALE cycle may include the following operations: (i) delivery of a reactant gas, (ii) purging of the reactant gas from the chamber, (iii) delivery of a removal gas and an optional plasma, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process; the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate, and can be supplied into the process chamber housing the substrate.

In order to perform these various processing operations, semiconductor processing tools, including those with one processing station in a processing chamber (“single-station tools”) and those with two or more processing stations in a single processing chamber (“multi-station tools”), have a process fluid delivery system that delivers numerous process fluids, such as process gases, liquids, fluids, and/or vapors (collectively referred to herein as “process gases” or “process gas”), to each processing station by flowing the each process gas from a common source through a manifold to a gas dispersion device, e.g., a showerhead, at the processing station. For multi-station tools, the process fluid delivery system delivers the numerous process fluids to each station by flowing each process gas from its common source through a gas manifold that has one or more junction points and multiple legs, or flowpaths, to the showerhead at each processing station. Although “showerhead” is used herein, such term encompasses any gas dispersion device, such as nozzles, ports, holes, or other structure that flows a gas or fluid into the processing chamber.

In order to flow multiple process gases to a single processing station, whether in a single-station or multi-station tool, that processing station may have a common junction manifold, hereinafter a “valve manifold,” where the inlets for the station come together, i.e., a common location where a leg of each of the multiple gas manifolds is physically and fluidically connected to the station. The valve manifold therefore includes multiple inputs that are each fluidically connected to one leg of each gas manifold. The valve manifold also includes a common outlet through which the gases flowed into the valve manifold flow into the gas dispersion device. In some implementations, the valve manifold may include a second outlet, e.g., a divert outlet, for diverting the process gases to a divert flow path and not to the processing chamber or processing station. The valve manifolds also include valves that control some of the gas flows into and through the valve manifold.

Some semiconductor processing tools flow a process gas, such as a precursor, and a purge gas through separate gas manifolds into the single, common valve manifold without providing a local flow control of the purge gas, e.g., without providing a valve on the valve manifold to control the flow of the purge gas into and/or through the valve manifold and to the showerhead. The present inventors discovered that this configuration can present various challenges and result in numerous disadvantages. For example, without flow control between the valve manifold and the purge gas manifold at the valve manifold, process gas can undesirably flow from the process gas manifold, into the valve manifold, and into the purge gas manifold. This backflow or backstream of the process gas into the purge gas manifold can cause numerous unwanted effects, such as deposition of a precursor in the purge gas manifold, damage to the purge gas manifold, and generation and flow of particles from the purge gas manifold onto the wafer. Some semiconductor processing tools prevent this backstream of process gas into the purge gas manifold by flowing the purge gas through the purge manifold at a low flowrate, sometimes referred to as a trickle purge, during one or more process steps, such as before, during, and/or after flowing the process gas. While this trickle purge may prevent some unwanted backflow of process gas into the purge gas manifold, the trickle purge can further cause unwanted effects, such as dilution of the process chemistry which can adversely affect process conditions. For instance, dilution of deposition process chemistry can undesirably slow growth rates or adversely affect deposited film properties.

Additionally, without local control of the purge gas at the valve manifold, the purge gas manifold may have an undesirably long leg and/or large dead leg volume. For example, some semiconductor processing tools flow the purge gas from its upstream source or upstream flow control point (e.g., a mass flow controller (MFC)) not locally positioned at or near the processing chamber, which results in a long leg (or long flowpath made up of multiple pipes, tubs, or other flow elements) having a large “dead leg” volume. Such configurations increase the purge gas flow control time which undesirably increases processing time. A dead leg generally refers to a volume of a gas or a portion of a fluid flow system where the gas or fluid can remain largely stagnant. These dead legs may be undesirable because, in some semiconductor processing, these dead legs may not be able to be properly cleaned which can lead to unwanted residue or buildup that can contaminate wafers. Further, some semiconductor processes use purge gases at a particular temperature, which may require temperature control, e.g., heating and maintaining the heat of, the purge gas. Having a purge gas manifold with a long leg and/or large dead leg volume makes this temperature control more challenging and for these processes, a purge gas at the incorrect temperature can cause undesirable effects.

A purge gas manifold with an undesirably long leg and large dead leg volume also can prevent charging the purge gas manifold and preforming a “burst purge.” It may be desirable to charge the purge gas manifold and thereby increase its pressure and concentration to more quickly and efficiently purge the gas dispersion device and processing station. However, this burst purge may not be feasible without local control of the purge gas manifold at the valve manifold. As described below, the present inventors determined that providing a valve manifold with local control of the purge gas manifold can result in numerous advantages including preventing unwanted backstream, enabling more precise purge gas flow, enabling a burst purge, and improving processing conditions by eliminating the trickle purge.

### Valve Manifolds and Apparatuses

Aspects of this disclosure pertain to improving flow control of a purge gas at a processing station by using a valve manifold as provided herein. The valve manifold includes a process gas inlet, a purge gas inlet, an outlet to the showerhead, and a divert outlet to the divert flowpath, as well as three valve interfaces with multiple ports that enable valves to control the flow control of the various gases within and through the valve manifold. When valves are interfaced with the valve manifold, the valve manifold and valves are configured to control the flow of the purge gas to the showerhead, such preventing the purge gas from flowing through the valve manifold and to the showerhead while the process gas is flowing to the showerhead, allowing the purge gas to flow through the valve manifold to the showerhead while being fluidically separate from the process gas, as well as control the flow of the process gas to the showerhead, such as allowing the process gas to flow through the valve manifold and to the showerhead while keeping the purge gas and purge gas manifold fluidically separate from the process gas, preventing the process gas from flowing to the showerhead and to the purge gas manifold, and allowing the process gas to flow to the divert flowpath.

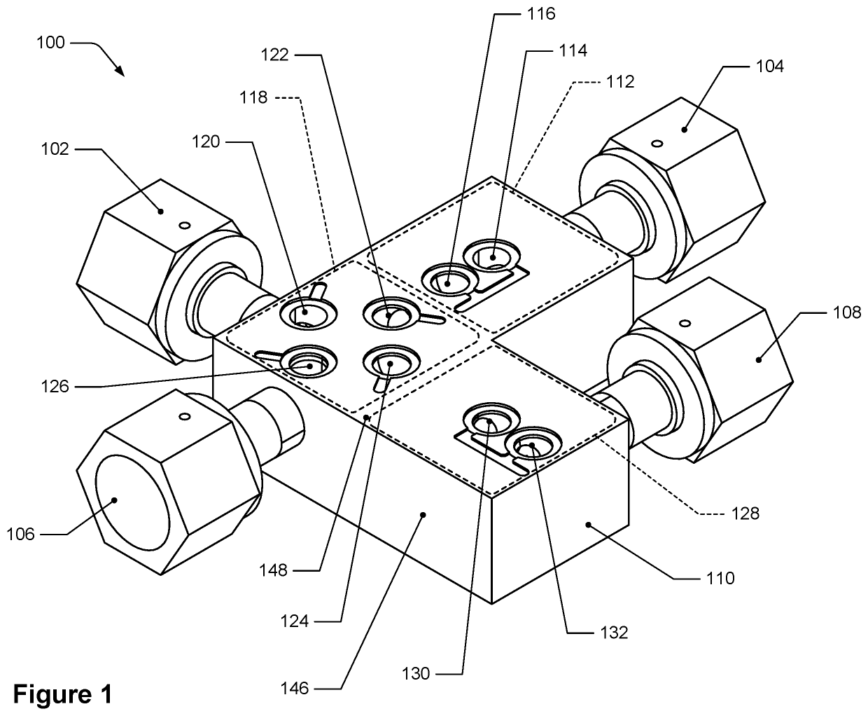

FIG. 1 depicts an off-angle view of a valve manifold according to disclosed embodiments. The valve manifold 100 includes a process gas inlet 102, a purge gas inlet 104, a manifold outlet 106, a divert outlet 108, and a manifold body 110. The process gas inlet 102 is configured to be fluidically connected to a process gas source (not shown) that is not located at or relatively close to the valve manifold, processing station, and processing chamber. Similarly, the purge gas inlet 104 is configured to be fluidically connected to a purge gas source (not shown) that is not located at or relatively close to the valve manifold, processing station, and processing chamber. The manifold outlet 106 is configured to be fluidically connected to an inlet of the processing station and to the showerhead of that processing station. The valve manifold 100 is also configured to be positioned in relatively close proximity to the showerhead as opposed to farther upstream at a gas box location. The manifold body 110 may be a block of material such as stainless steel or aluminum, that includes internal passages for transporting gases or fluids to various destinations.

Also shown in FIG. 1 are three valve interfaces that are each configured to interface with a valve, and each valve is configured to control the flow of gases within and through various aspects of the valve manifold. A first valve interface 112 is shown within a dashed box and includes a first port 114 and a second port 116. The first port 114 is fluidically connected with the purge gas inlet 104 via a first flowpath, not visible here, internal to the manifold body 110 and having no dead legs. The second port 116 configuration is discussed below.

A second valve interface 118 is also shown within a dashed box and includes a first port 120, a second port 122, a third port 124, and a fourth port 126. The first port 120 is fluidically connected with the process gas inlet 102 via a third flowpath, not visible here, internal to the manifold body 110 and having no dead legs. The second port 122 of the second valve interface 118 is fluidically connected with the second port 116 of the first valve interface 112 via a second flowpath, not visible here, internal to the manifold body 110 and having no dead legs. The third port 124 configuration is discussed further below. The fourth port 126 of the second valve interface 118 is fluidically connected with the manifold outlet 106 via a fifth flowpath, not visible here, internal to the manifold body 110 and having no dead legs.

A third valve interface 128 is shown within a dashed box and includes a first port 130 and a second port 132. The first port 130 of the third valve interface 128 is fluidically connected with the third port 124 of the second valve interface 118 via a fourth flowpath, not visible here, internal to the manifold body 110 and having no dead legs. The second port 132 is fluidically connected with the divert outlet 108 via a sixth flowpath, not visible here, internal to the manifold body 110 and having no dead legs.

Some features of the manifold body may be positioned in various locations and orientations in order to, for example, enable the valve manifold to be positioned near the showerhead, reduce its internal volume, reduce its total volume, and/or enable maintenance to be performed on the valve manifold. In some embodiments, as illustrated in FIG. 1, the manifold outlet 106 may be located on a first side 146 of the manifold body 110 and the first valve interface 112 may be located on a second side 148 of the manifold body 110. These first and second sides are different than each other. As also illustrated, in some embodiments, the first valve interface 112, the second valve interface 118, and the third valve interface 128 may all be on the same side, i.e., the second side 148, of the manifold body 110. In some other embodiments, the first valve interface 112, the second valve interface 118, and the third valve interface 128 may all be different sides of the manifold body 110, such as the second valve interface 118 being on a third side and the third valve interface 128 being on a fourth side.

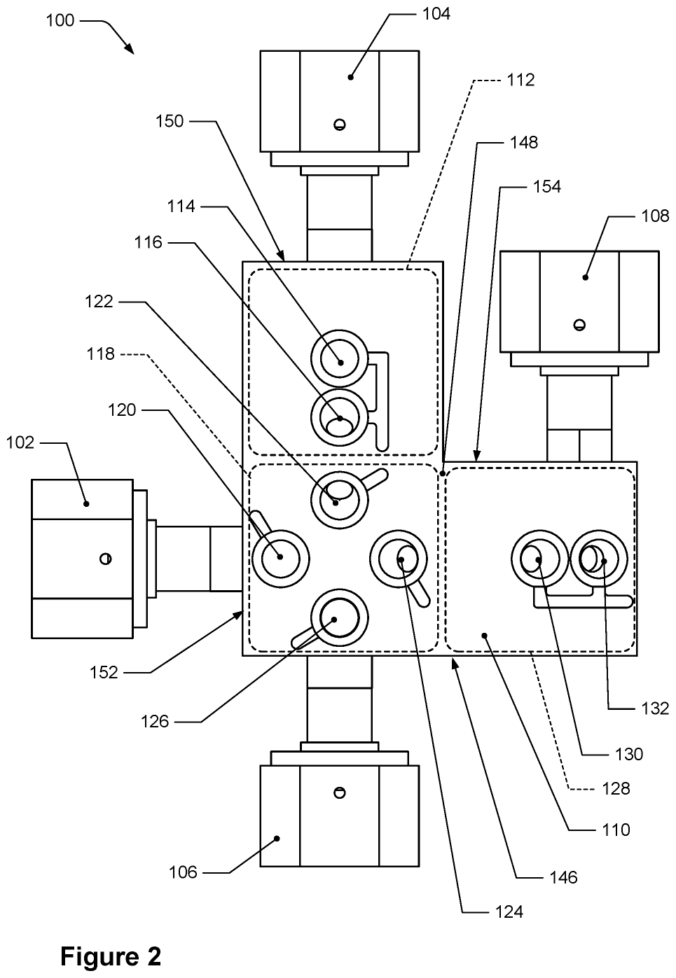

In some embodiments, as shown in FIG. 1, the process gas inlet 102 and the purge gas inlet 104 may be on different sides than each other and different than the first and second sides. For example, as shown in FIG. 2 which depicts a top view of valve manifold of FIG. 1, the purge gas inlet 104 may be on a third side 150 of the manifold body 110 and the process gas inlet 102 may be on a fourth side 152 of the manifold body 110. In some embodiments, the manifold outlet 108 may be on a fifth side 154 of the manifold body 110. In some instances, the first side 146 and the third side 150 may be parallel, or substantially parallel (e.g., within about 10% of parallel), to each other. The fifth side 154 may also be parallel, or substantially parallel (e.g., within about 10% of parallel), to the first side 146 and the third side 150. In some embodiments, like shown in FIGS. 1 and 2, the first side 146, the third side 150, and the fourth side 152 are orthogonal, or substantially orthogonal (e.g., within about 10% of orthogonal), to the second side 148. In some embodiments, as depicted in FIG. 2, the manifold body 110 may have an L-shape. In some instances, the second valve interface 118 may be interposed between and immediately adjacent to both the first valve interface 112 and the third valve interface 128.

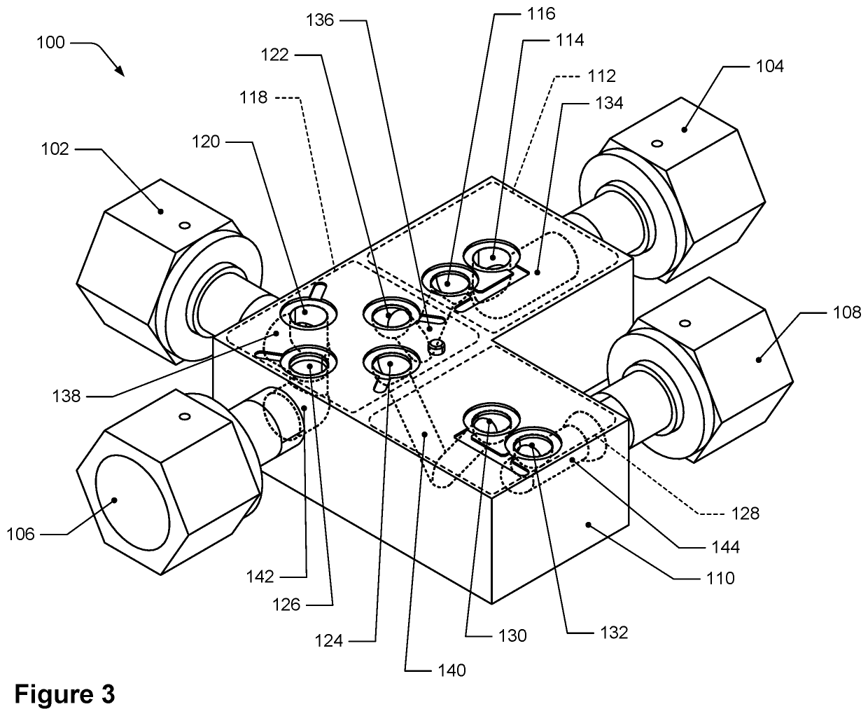

FIG. 3 depicts the off-angle view of the valve manifold of FIG. 1 and various internal features of the valve manifold. Here, along with the features of FIG. 1, some of the valve manifold's internal flowpaths are shown with broken lines. Each of the depicted flowpaths extend through the manifold body 110, have no dead legs, and provide fluidic connections. The first flowpath 134 fluidically connects the purge gas inlet 104 with the first port 114 of the first valve interface 112, the second flowpath 136 fluidically connects the second port 116 of the first valve interface 112 with the second port 122 of the second valve interface 118. Further, the third flowpath 138 fluidically connects the process gas inlet 102 with the first port 120 of the second valve interface 118, the fourth flowpath 140 fluidically connects the third port 124 of the second valve interface 118 with the first port 130 of the third valve interface 128, the fifth flowpath 142 fluidically connects the fourth port 126 of the second valve interface 118 with the manifold outlet 106, and the sixth flowpath 144 fluidically connects the second port 132 of the third valve interface 128 with the divert outlet 108.

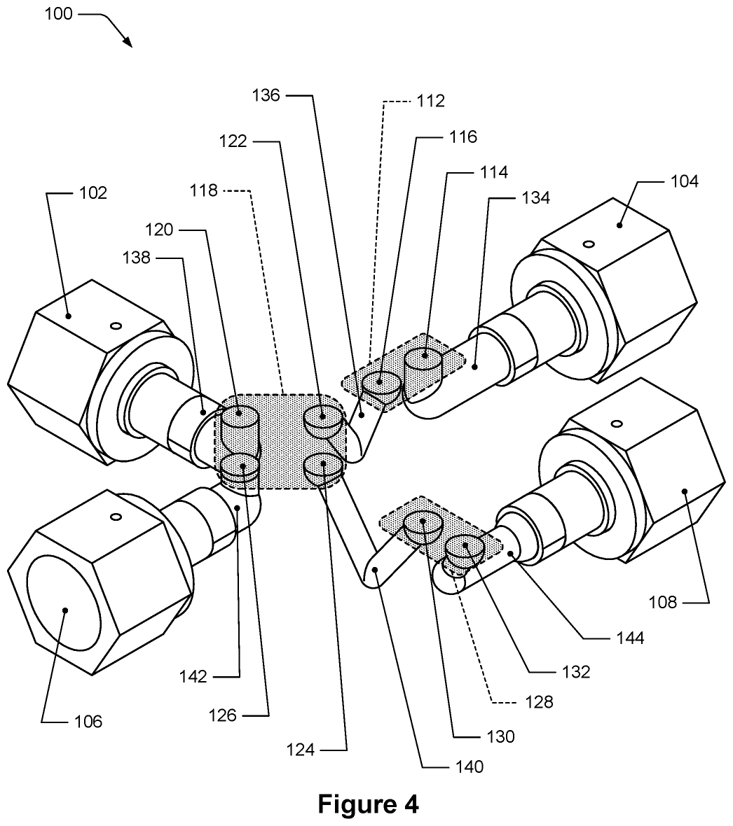

These flowpaths are further illustrated in FIG. 4 which depicts an off-angle view of the internal flowpath volumes of the valve manifold of FIG. 3. Here, the illustrated portions of the manifold body are the internal volumes of each of the six flowpaths 134-144. In some implementations, as can be seen, the internal flowpaths of the valve manifold 100 have various geometries, such as elbows oriented at different various angles and having different shapes, such as a “V” shape or an “L”. The use of these geometries, e.g., elbows, allows for dense packaging of the valves used on the valve manifold. This may be of particular benefit given that the valve manifold may be mounted in very close proximity to the showerhead and space constraints in such locations may severely limit the size of such valve manifolds. The shaded areas represent the three valve interfaces, i.e., 112, 118, and 128, where valves may be connected to the valve manifold and used for controlling the flow of gases through and within the valve manifold 100.

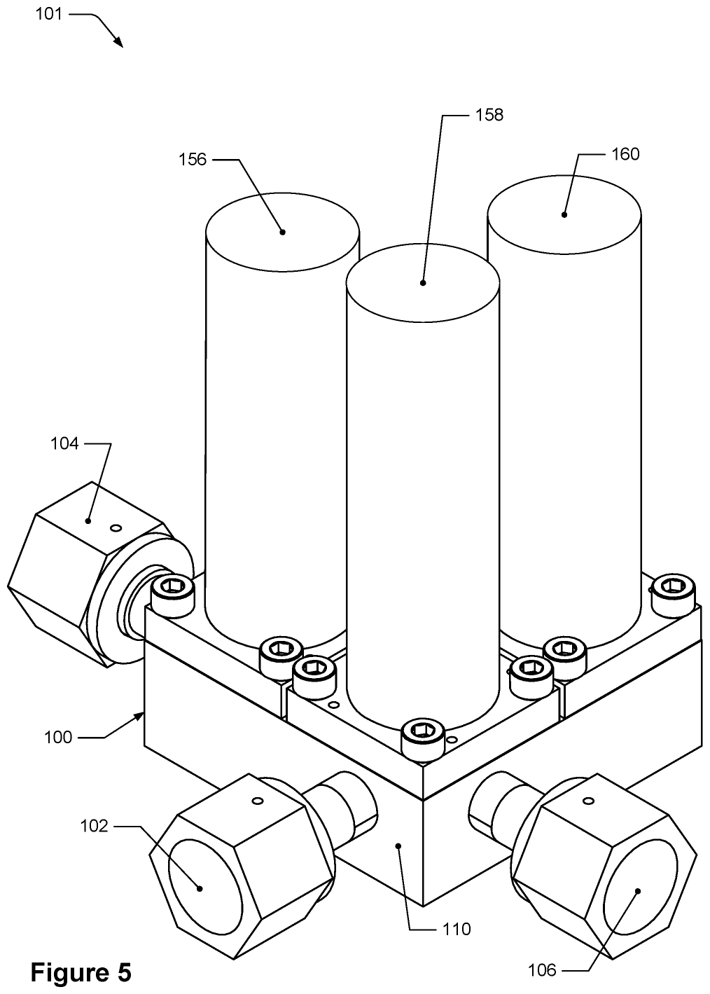

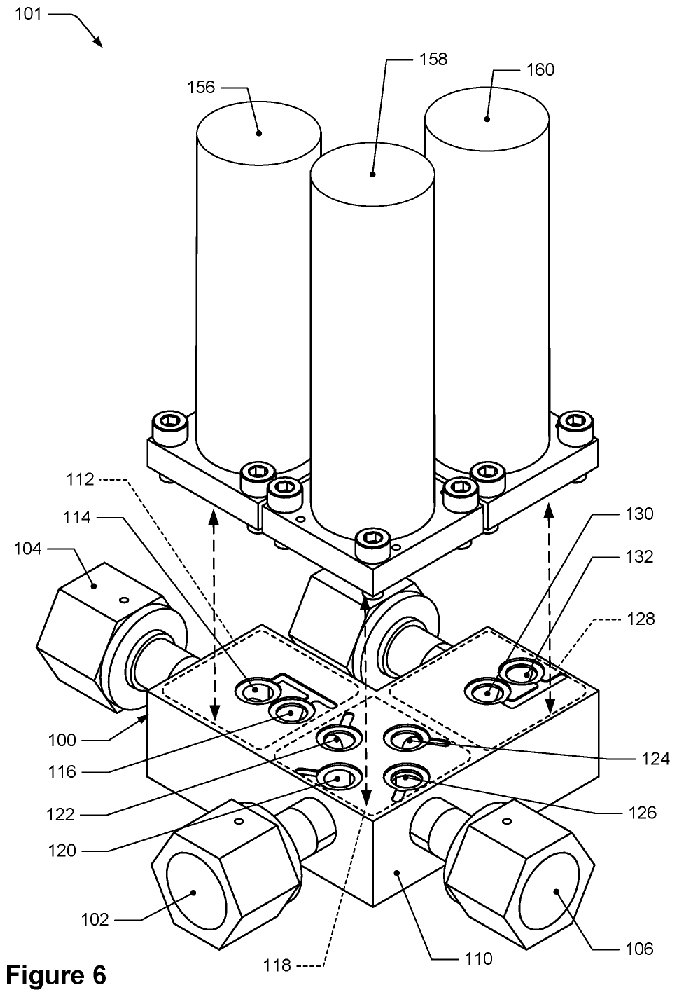

The valve manifold described herein is used with a plurality of valves to control flow through and within the valve manifold. FIG. 5 depicts an off-angle view of an apparatus that includes the valve manifold of FIG. 1 and a plurality of valves interfaced with the valve manifold and FIG. 6 depicts an exploded view of the apparatus of FIG. 5. The viewing angle in FIGS. 5 and 6 is different than FIG. 1 and here in FIG. 5, the valve manifold 100, the manifold body 110, the process gas inlet 102, the purge gas inlet 104, and the manifold outlet 106 are seen. The apparatus 101 includes three valves connected and attached to the manifold body 110, and therefore interfaced with the manifold 100, i.e., a first valve 156, a second valve 158, and a third valve 160. As illustrated in FIGS. 5 and 6, the first valve 156 is interfaced with the first valve interface 112, the second valve 158 is interfaced with the second valve interface 118, and the third valve 160 is interfaced with the third valve interface 128. As explained herein, these valves are switchable between open and closed states to allow and to prevent fluidic communication between at least some of the ports of each valve interface.

The first valve 156 is configured to be switchable between an open state and a closed state, and when interfaced with the first valve interface 112, is also configured to control flow between the first port 114 and the second port 116 of the first valve interface 112. In some instances, the open state of the first valve 156 may include a fully open state in which flow is unrestricted or one or more partially open states in which a semi-restricted flow is allowed between the first port 114 and second port 116; the closed state of the first valve 156 may fully restricted flow between the first port 114 and second port 116 and therefore prevent any flow between these two ports. Similarly, the third valve 160 is configured to be switchable between an open state and a closed state, and when interfaced with the third valve interface 128, is configured to control flow between the first port 130 and the second port 132 of the third valve interface 128. In some instances, the open state of the third valve 160 may include a fully open state in which flow is unrestricted or one or more partially open states in which a semi-restricted flow is allowed between the first port 130 and second port 132; the closed state of the third valve 160 may fully restricted flow between the first port 130 and second port 132 and therefore prevent any flow between these two ports.

The second valve 156 is configured to be switchable between an open state and a closed state, and when interfaced with the second valve interface 118, is configured to control the flow of the ports of the second interface 118 as explained herein. For example, when in the open state, the second valve 156 may allow flow between the first port 120 and the fourth port 126 of the second valve interface 118 and not between the first port 120 and the third port 124 of the second valve interface 118. In the closed state, for instance, the second valve 156 may allow flow between the first port 120 and the third port 124 of the second valve interface 118 and not between the first port 120 and the fourth port 126 of the second valve interface 118. In some instances, the second port 122 of the second valve interface 118 may be fluidically connected to the fourth port 126 when the second valve 158 is in the open and closed configurations.

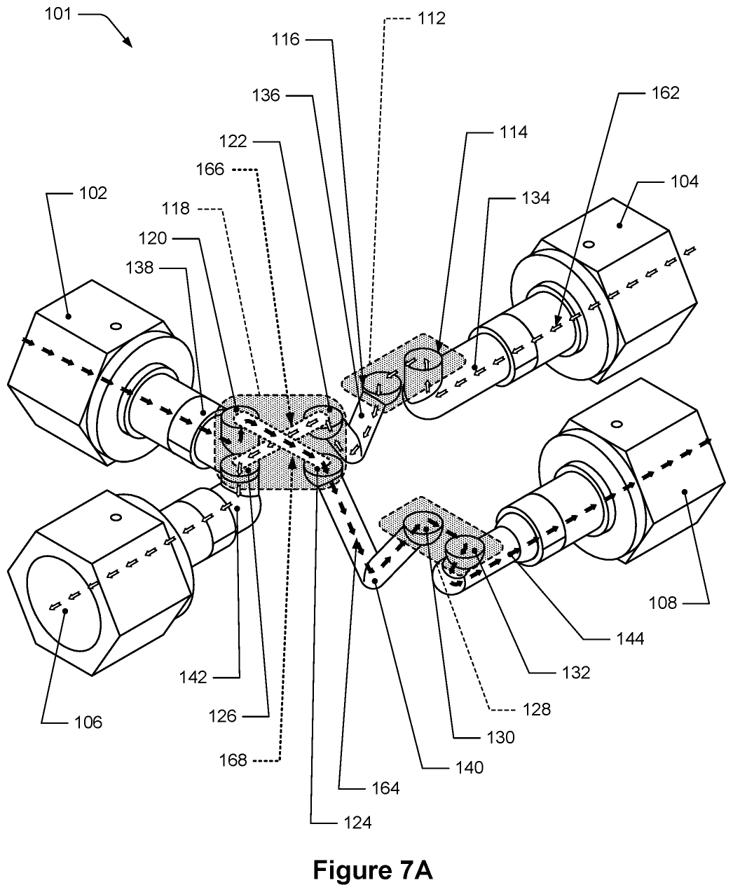

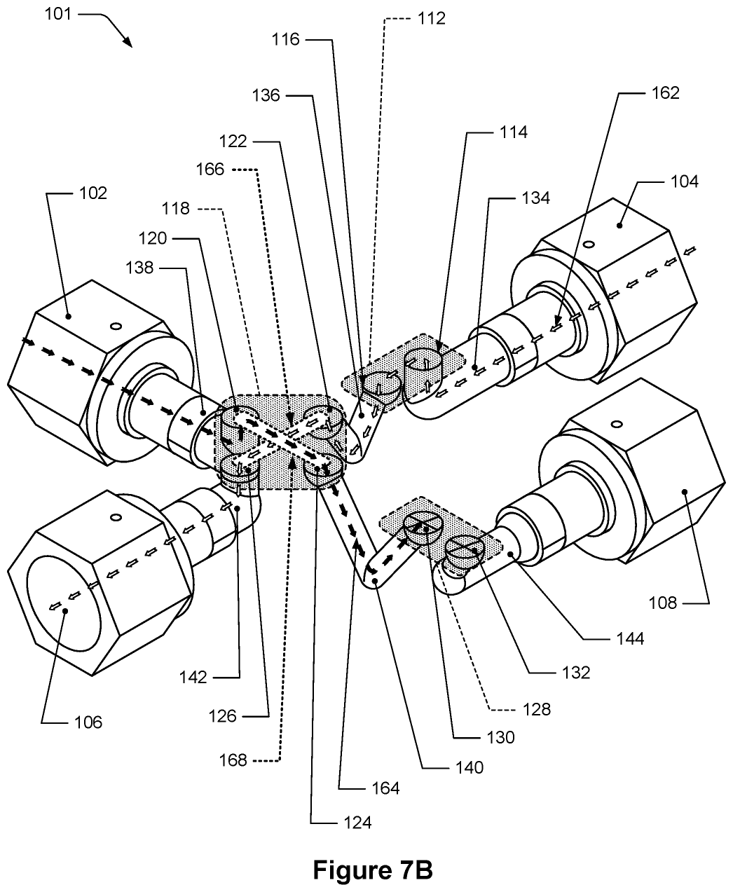

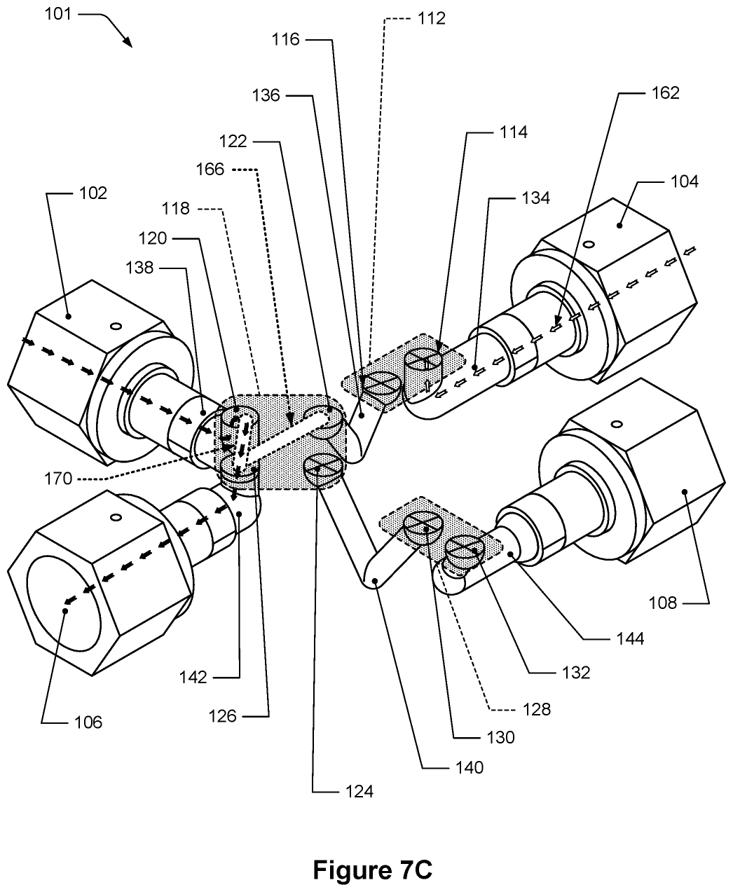

The valves and their configurations are able to control the flow in and within the valve manifold as described in more detail with respect to FIGS. 7A-7C. In FIGS. 7A-7C, the apparatus of FIGS. 5 and 6 is depicted, but for clarity and illustration purposes, the internal flowpaths and valve interfaces of FIG. 4 are shown while the remaining manifold body and first, second, and third valves are not shown; however, in these FIGS. 7A-7C, the first, second, and third valves are considered present and interfaced with the valve manifold as described herein and shown in FIGS. 5 and 6. FIG. 7A depicts the apparatus's valve manifold flowpaths and valve interfaces of FIG. 4 and various gas flows according to disclosed embodiments. Here in FIG. 7A, the apparatus 101 is shown, but only the valve manifold's internal features and valve interfaces, like that in FIG. 4 are depicted; the first, second, and third valves are considered interfaced with the valve manifold as described herein. Here in FIG. 7A, the first valve is interfaced with the first valve interface 112 and in an open state thereby fluidically connecting the first port 114 and the second port 116 of the first valve interface 112. The first valve in the open state also fluidically connects the first flowpath 134 with the second flowpath 136 such that purge gas can flow from the purge inlet 104 to the second flowpath 136. The purge gas flow is represented by white arrows 162. As can be seen, purge gas 162 flows through the purge inlet 104 to the first flowpath 134, through the first flowpath 134 and through the first port 114 of the first valve interface 112, to a fluidic region at least partially bounded by the first valve, through the second port 116 of the first valve interface 112, and through the second flowpath 136.

In some implementations, once the purge gas reaches the second port 122 of the second valve interface 118, depending on the configuration of the second valve, not pictured, the purge gas may be able to flow to the manifold outlet 106. In some such implementations, as noted above, the second valve may fluidically connect the second port 122 of the second valve interface 118 with the fourth port 126 when the second valve 158 is in any configuration, such as in the open and closed configurations. This may fluidically connect the second port 122 of the second valve interface 118 with the fourth port 126 of the second valve interface 118, and thereby fluidically connect the second port 122 to the fifth flowpath 142 and the manifold outlet 106. Accordingly, in some such implementations, when the first valve is in the open state, the purge gas inlet 104 may be fluidically connected to the manifold outlet 106. This fluidic connection may be the purge gas inlet 104 being fluidically connected to the first flowpath 134, the first flowpath 134 being fluidically connected to the second flowpath 136 as provided by the first valve, and the second flowpath 136 being fluidically connected to the fifth flowpath 142 and the manifold outlet 106 as provided by the second valve. As noted above, the fluidic connection between the purge gas inlet 104 and the manifold outlet 106 is represented by the white arrows 162.

The second valve is also configured to provide various flow controls and fluidic connections. In some embodiments, the second valve may be configured such that when it is interfaced with the second valve interface 118, the second port 122 is fluidically connected to the fourth port 126 in any and all of the second valve states, such as the open state, partially open state, and the closed state. In FIG. 7A, the second valve is interfaced with the second valve interface 118 and in the closed state, and when in this configuration, the first port 120 of the second valve interface 118 is fluidically connected to the third port 124 of the second valve interface 118 and not fluidically connected to the fourth port 126, thereby preventing process gas from flowing from the first port 120 to the fourth port 126. The black arrows 164 represent the flow of process gas which can be seen flowing from the process gas inlet 102, through the third flowpath 138, through the first port 120, through the third port 124 of the second valve interface 118, and into the fourth flowpath 140.

It will be understood that the second valve is configured to provide at least two fluidically separate, fluidically isolated, and fluidically independent flowpaths through the second valve. As illustrated in FIG. 7A, for instance, the second valve provides a first internal flowpath, represented by an ellipse 166, between the second port 122 and the fourth port 126, and a second internal flowpath, represented by ellipse 168, between the first port 120 and the third port 124 that is fluidically separate from and independent of the first internal flowpath 166. As described below, the second valve may also be configured to provide a third internal flowpath, fluidically separate and independent of the first internal flowpath 166, that fluidically connects the first port 120 and the fourth port 126. These internal flowpaths are not intended to represent the actual shapes of such flowpaths and are instead illustrative representations.

Positioning the second valve in the closed state provides various advantages. For example, the purge gas can be flowed into and through valve manifold 100, out the manifold outlet 106 and into the processing station, independent of and fluidically separate from the process gas. Additionally, the process gas can flow into and through the valve manifold 100 can be further controlled, e.g., stopped or flowed to the divert outlet 108. For various processing operations, it is desirable to flow the process gas through the manifold outlet 106 and onto a wafer in the processing chamber at some specific times and phases during processing operations, and not onto the wafer at other times and phases of the processing operations. For example, some ALD processes may flow the process gas, e.g., a precursor, during the dose phase, but not during the purge phases or the activation phase. With the valve manifold and valves herein, by positioning the second valve in the closed state, the process gas is prevented from flowing through the fourth port 126, through the manifold outlet 106, and into the processing chamber.

The flow of the process gas through the valve manifold 100 is further controlled by the third valve when it is interfaced with the third valve interface 128. When the third valve is interfaced with the third valve interface 128, the third valve is configured to control gas flow between the first port 130 and the second port 132 of the third valve interface 128. In FIG. 7A, the third valve, not pictured, is interfaced with the third valve interface 128 and in an open state thereby fluidically connecting the first port 130 and the second port 132 of the third valve interface 128. The third valve in the open state also fluidically connects the fourth flowpath 140 with the sixth flowpath 144 such that process gas can flow from the process gas inlet 102 to the divert outlet 108. As can be seen with the black arrows 164, process gas flows through the process gas inlet 102, to the third flowpath 138, through the third flowpath 138, through the first port 114, through the internal flowpath 168 provided by the second valve, through the third port 124, through the fourth flowpath 140, through the first port 130 of the third valve interface 128, through the second port 132 of the third valve interface 128, through the sixth flowpath 144, and through the divert outlet 108.

In some implementations, the third valve is therefore configured to control the flow of the process gas to the divert outlet. This may include when the second valve is in the closed state and the first port 120 of the second valve interface 118 is fluidically connected to the third port 126 of the second valve interface. In some embodiments, when it is desired to stop the process gas flow to the processing chamber and showerhead therein, it may be advantageous to divert the process gas to the divert outlet, instead of stopping its flow. The valve manifold 100 and corresponding valves enable such operation by, as illustrated in FIG. 7A, positioning the second valve in the closed state such that the first port 120 of the second valve interface 118 is fluidically connected to the third port 126 of the second valve interface 118 and positioning the third valve in the open state to fluidically connect the first port 130 and the second port 132 of the third valve interface 128 and thus fluidically connect the process gas inlet 102 and the divert outlet 108.

In some embodiments, additionally or alternatively, it may be advantageous to stop the flow of the process gas through the valve manifold by configuring the third valve in the closed state. FIG. 7B depicts the apparatus's valve manifold flowpaths and valve interfaces of FIG. 4 and alternate gas flows according to disclosed embodiments. Here, the third valve is in the closed state, such that the first port 130 is not fluidically connected to the second port 132 of the third valve interface 128 as indicated by the “X” in the first and second ports 130 and 132. Because of this, the process gas inlet 102 is not fluidically connected to the divert outlet 108 or the manifold outlet 106 and process gas does not flow to either outlet in this implementation.

FIGS. 7A and 7B may be considered a purge phase or operation of a processing operation. This purge phase includes flowing the purge gas through the valve manifold 100 to the manifold outlet 106 that is fluidically connected to the processing station, while not flowing the process gas to the manifold outlet 106 and not to the processing station. For ALD operations, this purge may be performed before a dose phase, after a dose phase and before an activation phase, after the activation phase, or a combination thereof. For ALE operations, this purge may be performed before a modification operation, after a modification operation and before removal operation, after the removal operation, or a combination thereof

The flow of the process gas to the manifold outlet 106 and to the processing chamber will now be discussed. In some embodiments, the process gas may be flowed to the manifold valve outlet 106 by configuring the second valve in the open state. FIG. 7C depicts the apparatus's valve manifold flowpaths and valve interfaces of FIG. 4 and various gas flows according to disclosed embodiments. As with FIGS. 7A and 7B, the apparatus 101 is shown, but only the valve manifold's internal features and valve interfaces, like that in FIG. 4 are depicted; the first, second, and third valves are considered interfaced with the valve manifold as described herein. Here in FIG. 7C, the second valve is in the open state (e.g., a fully open or partially restricted flow state) such that the first port 120 of the second valve interface 118 is fluidically connected to the fourth port 126 of the second valve interface 118, and the first port 120 is not fluidically connected to the third port 124. Because gas is not configured to flow from the first port 120 to the third port 124 of the second valve interface 118 when the second valve is in the open state, the third port 124 has an “X” indicating it may be a closed port. In some implementations, when the second valve is in the closed state, gas may not be configured to flow from either the first port 120 or the second port 122 to the third port 124. The process gas, represented by the black arrows 166, is therefore configured, and able, to flow from the process gas inlet 102 to the manifold valve outlet 106, and not to flow to the third port 124. The second valve may provide a third internal flowpath, represented by ellipse 170, that is an independent fluidic connection between the first port 120 and the fourth port 126 when the second valve is in the open state.

In some embodiments, while the process gas is flowed through the valve manifold to the manifold outlet 106, e.g., by having the second valve in the open state, the first valve is in a closed state, as indicated by the “X” on the first port 114 and second port 116 of the first valve interface 112, thereby preventing the purge gas from flowing through the first port 114 and into the second port 116 and second flowpath 136. This is illustrated by the purge gas arrows 162 stopping at the first port 114. Because the second valve may provide the fluidic connection 166 between the fourth port 126 and the second port 122 of the second valve interface 118 when in the open configuration, the first valve being configured to the closed state when the second valve is in the open state prevents unwanted backflow of the process gas to the purge gas manifold that is fluidically connected to the purge gas inlet 104. By preventing the unwanted backflow of process gas into the purge gas manifold, a trickle purge, e.g., a constant flow of purge gas through the purge gas manifold while the process gas is flowed to the showerhead, is not needed. This provides numerous benefits, such as reducing or eliminating the unwanted dilution of the process gas which improves performance of the processing operations, such as improved deposition growth rate and reduced defects.

Configuring the first valve in the closed state while the process gas is flowing to the manifold outlet 106 further allows for the purge manifold to be charged, and in some instances pressurized, which provides numerous advantages, such as increasing the purge gas concentration and pressure inside the purge gas manifold to provide a burst purge through the manifold and into the showerhead. This burst purge can purge the showerhead faster by more efficiently (given its higher concentration) as compared to traditional purges. This can reduce the time required for a purge, and also perform a better purge.

This configuration of the apparatus 101 also creates a small purge gas leg and volume between the showerhead and the first valve, instead of the larger purge gas leg between the showerhead and the purge gas source. By having a smaller purge gas leg and volume, the purge gas flow control is faster and also reduces or eliminates the need for the complex temperature control of the purge gas manifold and its associated unwanted effects.

In some embodiments, while the second valve is in the open state, the third valve may be in a closed state, as indicated by the “X” on the first port 130 and second port 132 of the third valve interface 128, thereby preventing the process gas from flowing through the first port 130 and into the second port 132, sixth flowpath 144, and out through the divert outlet 108. In some embodiments, as an extra safety precaution, the second valve and the third valve may be interlocked such that when the second valve is in the open state, the third valve is in the closed state, and when the second valve is in the closed state, the third valve is in the open state.

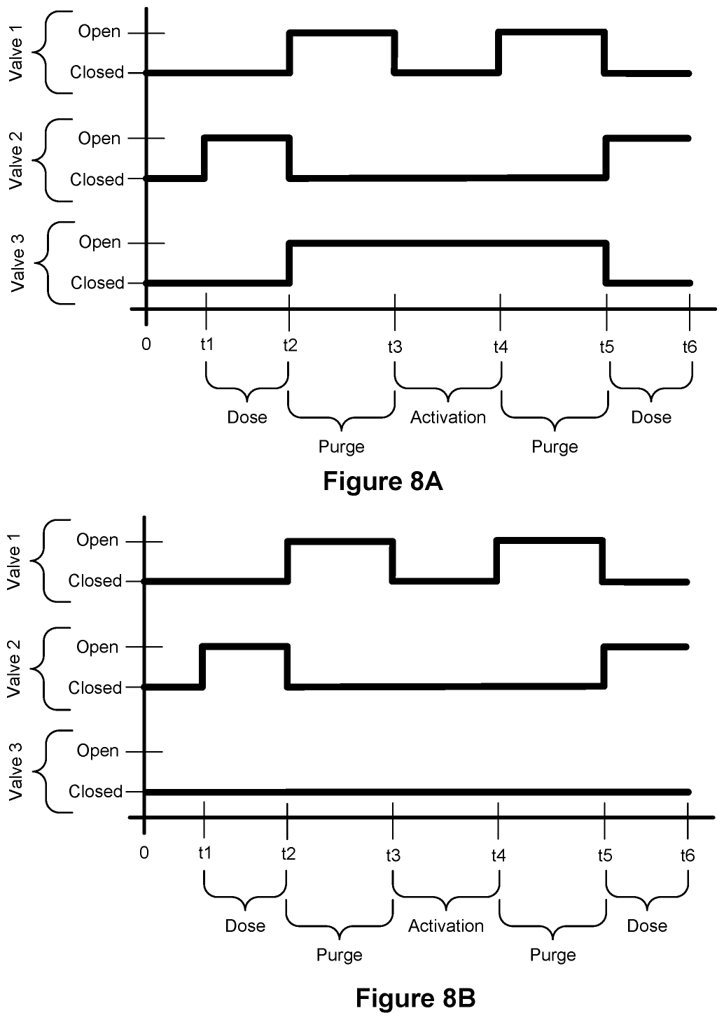

Further examples of the valve operations and gas flows through the valve manifold of the apparatus will now be described. FIG. 8A depicts a valve operation and timing diagram according to disclosed embodiments. Here, the vertical axis includes the three valves described herein and their configuration state, i.e., whether the respective valve is in an open state or a closed state. The horizontal axis represents time and the phase of operation for various processing operations; here it represents phases of ALD operations but may also represented phases of ALE operations. Between time 0 and time t1, all the valves are closed. At time t1, the process gas is flowed to the manifold outlet and the showerhead fluidically connected thereto in the processing station. As illustrated in FIG. 8A, the process gas is flowed to the manifold outlet by configuring the first valve in the closed state, the second valve the open state, and the third valve in the closed state. This configuration corresponds with the illustration of FIG. 7C such that the second valve is in the open configuration which allows the process gas to flow through the first port 120 of the second valve interface 118 to the fourth port 126 of the second valve interface 118 and out the manifold outlet 106 to the showerhead fluidically connected thereto. With the first valve in the closed state, the purge gas does not flow through the second port 116 of the first valve interface 112, through the second port 122 of the second valve interface 118, and therefore does not dilute the process gas. The process gas is also prevented from undesirably backflowing through the second port 116 of the first valve interface 112 and to the purge gas manifold. Accordingly, in this configuration and for this time period, the purge gas and the process gas are fluidically isolated from each other in this configuration.

Referring back to FIG. 8A, the process gas may be flowed to the showerhead and wafer from time t1 to time t2 after which it may be stopped. In some deposition processes, this time period may be considered a dose phase; in some etching processing, this may be considered a modification operation. When the desired time for flowing the process gas to the showerhead is complete at time t2, a purge operation may be performed at time t2. The purge operation includes, in some implementations, positioning the first valve in the open state and the second valve in the closed state. As provided above, some embodiments may have the third valve in the open state while others may have the third valve in the closed state. FIG. 8A illustrates the third valve in the open state thereby allowing the process gas to flow to the divert outlet.

The purge times of FIG. 8A, such as between times t2 and t3, and between times t4 and t5, correspond with the illustration of FIG. 7A such that the first valve is in the open state which allows the purge gas to flow through the second port 116 of the first valve interface 112, through the second flow path 136, through the second port 122 of the second valve interface 118, through the fourth port 126 of the second valve interface 118 and out the manifold outlet 106 to the showerhead fluidically connected thereto. Additionally, the second valve is in the closed state which allows the process gas to flow through the first port 120 of the second valve interface 118 to the third port 124 of the second valve interface 118 and with the third valve in the open state, the process gas can continue flowing through the first port 130 and second port 132 of the third valve interface 128 and out the divert outlet 108. The purge gas and the process gas are again fluidically isolated from each other in this configuration during this time period.

In some embodiments, from at least times t1 through time t3, the process gas may be continuously flowing from the process gas source towards the processing station, but as described herein, it is directed to the showerhead and wafer for only a part of this time period and directed to the divert flowpath for another part of this time period. This configuration of the apparatuses provided herein enable this continuous process gas flow and such continuous gas flow presents numerous advantages, such as maintaining relatively constant and stable process gas flow conditions, e.g., flowrate and pressure, thereby reducing process gas variability, and also providing fast process gas control response time by having the process gas located at the valve manifold and close to the showerhead at the start of the dose period as opposed to waiting for the processing gas to flow from the gas source to the valve manifold.

In some other embodiments, the process gas may not continuously flow through the valve manifold and instead it may be stopped as illustrated in FIG. 7B. FIG. 8B depicts an alternate valve operation and timing diagram. Here, at time t2, the third valve remains closed, as opposed to being opened in FIG. 8A, thereby stopping the flow of the processing gas through the valve manifold from both the manifold outlet and the divert outlet.

Referring back to FIG. 8A, the purge operation may be performed between time t2 and t3, after which other processing operations may be performed. For deposition processes, this may include the activation phase which may, in some instances, not include flowing any other process gases to the showerhead and in some other instances, include flowing other process gases through other manifolds to the showerhead. These other processing operations may occur between time t3 and t4 of FIG. 8A during which time at least both the first valve and second valve are closed in order to prevent the process gas and the purge gas from flowing through the manifold outlet and to the showerhead. In FIG. 8A, the third valve remains open between time t3 and t4 to allow the purge gas to flow continuously through the valve manifold and out the divert outlet (as illustrated in FIG. 7A).

After time t4 in FIG. 8A, another purge may be performed from time t4 to time t5. This purge may again be performed as indicated in FIG. 7A with the first valve in the open state and the second valve in the closed state. In FIG. 8A, the process gas is still able to flow through the manifold and out the divert outlet with the third valve in the open state. In FIG. 8B, the purge is also performed between time t4 and t5, but again the process gas is prevented from flowing through either outlet of the manifold with both the second and third valves in the closed state. The time between time t1 and time t5 may be considered a single cycle of operation, such as a single ALD or ALE cycle.

After time t5, another cycle may be performed from time t5 to time t6 in FIG. 8A, which includes another phase in which the process gas is flowed through the manifold to the manifold outlet and to the showerhead, like between times t1 and t2, such as another dose phase. Again, the first valve may be in the closed state, the second valve may be in the open state, and the third valve may be in the closed state as described herein above and illustrated, for example, in FIG. 7C. In FIG. 8B, the third valve may remain in the closed state between times t1 and t6, for example.

### Techniques

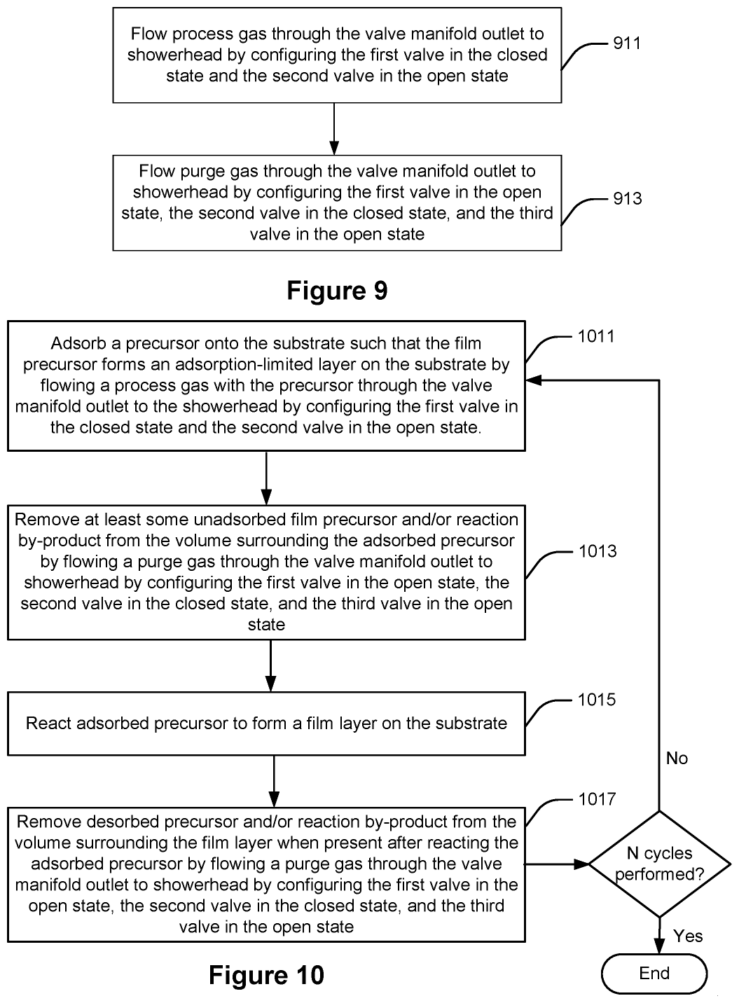

The valve manifolds and apparatuses provided herein may be used various processing techniques and operations, such as ALD or ALE, to deposit or etch material. FIG. 9 depicts a first example technique according to disclosed embodiments. Here in block 911, the process gas is flowed to the wafer by flowing the process gas through valve manifold and to the manifold outlet by configuring the second valve in the open state and the first valve in the closed state as described herein above and shown in FIG. 7C, for example, and from time t1 to time t2 in FIGS. 8A and 8B. The process gas is able to flow through the first port 120 of the second valve interface 118 to the fourth port 126 of the second valve interface 118 and out the manifold outlet 106 to the showerhead fluidically connected thereto and the corresponding wafer. With the first valve in the closed state, the purge gas does not flow through the manifold, such as through the second port 116 of the first valve interface 112 and the process gas is prevented from backflowing through the second port 116 of the first valve interface 112 and to the purge gas manifold, thereby fluidically isolating the purge gas manifold from the process gas manifold.

Block 911 may correspond to a dose phase of an ALD cycle during which precursor is flowed to the showerhead and corresponding wafer, or to a modification phase of an ALE cycle during which a modifying gas is flowed to the showerhead and corresponding wafer. In some instances, as provided herein, the third valve may also be in the closed state during block 911.

In block 913, the purge gas is flowed to the showerhead and corresponding wafer by, as provided above, configuring the first valve in the open state and the second valve in the closed state. This enables the purge gas to flow through the second port 116 of the first valve interface 112, through the second flow path 136, through the second port 122 of the second valve interface 118, through the fourth port 126 of the second valve interface 118 and out the manifold outlet 106 to the showerhead and wafer. With the second valve in the closed state, the process gas can flow through the first port 120 of the second valve interface 118 to the third port 124 of the second valve interface 118 and with the third valve in the open state, the process gas can continue flowing through the first port 130 and second port 132 of the third valve interface 128 and out the divert outlet 108.

Block 913 may correspond with a purge phase of an ALD cycle or an ALE cycle. For ALD cycles, as illustrated in FIG. 8A for instance, the purge of block 913 may be performed after the dose phase and before the activation phase, and then after the activation phase. For ALE cycles, the purge of block 913 may be performed after the modification operation and before a removal operation, and then after the removal operation.

FIG. 10 depicts a flowchart of an example sequence of operations for forming a film of material on a substrate via an ALD process. As stated above, a typical ALD cycle includes (1) exposure of the substrate surface to a first precursor, (2) purge of the reaction chamber in which the substrate is located, (3) activation of a reaction of the substrate surface, e.g., with a plasma, a second precursor, a thermal energy, or a combination thereof, and (4) purge of the reaction chamber in which the substrate is located. As can be seen in FIG. 10, item 1 above corresponds with block 1011 in which the process gas comprising a precursor is flowed through the valve manifold and onto the wafer as described herein, including block 911 and FIG. 7C. Item 2 above corresponds with block 1013 in which a purge is performed by flowing the purge gas through the valve manifold as described herein, including block 913 and FIG. 7A or 7B. Item 3 above corresponds with block 1015, and item 4 above corresponds with block 1017 in which another purge operation is performed by flowing the purge gas through the valve manifold as described herein, including block 913 and FIG. 7A or 7B. The four blocks are performed for N cycles, after which the process is stopped.

For ALE, these processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts, as well as a cleaning operation to remove residues that have built up on surfaces of the processing chamber. Generally, a cycle contains one instance of a unique sequence of operations. As an example, an ALE cycle may include the following operations: (i) delivery of a first process gas that is a reactant gas, (ii) purging of the reactant gas from the chamber, (iii) delivery of a second process gas that is a removal gas and an optional plasma, and (iv) purging of the chamber. The modification operation (item (ii) above) generally forms a thin, reactive surface layer with a thickness less than the un-modified material, such as one, two, or three, atomic layers thick, for instance, or less than a whole atomic layer in one cycle.

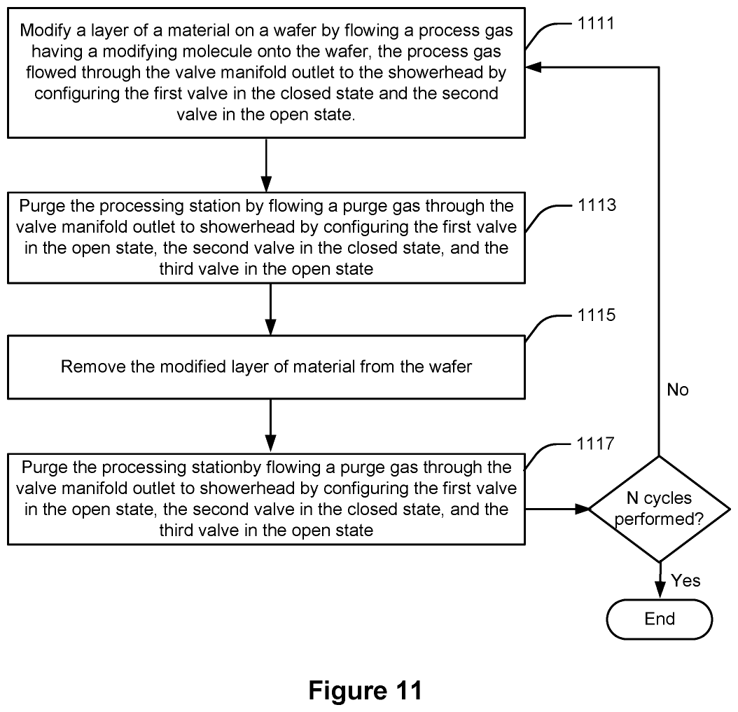

FIG. 11 depicts a flowchart of an example sequence of operations for etching a layer of material from a wafer via an ALE process. Block 1111 corresponds with operation (i) directly above in which the process gas having a modifying molecule, e.g., a reactant gas, is flowed onto the wafer by flowing it through the valve manifold and onto the wafer as described herein, including block 911 and FIG. 7C. Blocks 1113 and 1117 correspond with operations (ii) and (iv) directly above in which a purge is performed by flowing the purge gas through the valve manifold as described herein, including block 913 and FIG. 7A or 7B. Block 1115 correspond with operation (iii) above. In some instances, this removal operation may include flowing another process gas onto the wafer, using a plasma, a thermal energy, or combination thereof, to remove the modified layer of material. The four blocks are performed for N cycles, after which the process is stopped.

### Additional Apparatuses

The valve manifolds and apparatuses herein may be incorporated to semiconductor processing tools and chambers in order to control the flow of a process gas and a purge gas to a processing station in the processing chamber, including controlling such flows to multiple stations of a multi-station processing chamber and the station of a single-station chamber and these chambers may be used to perform various processing operations such as deposition or etching.

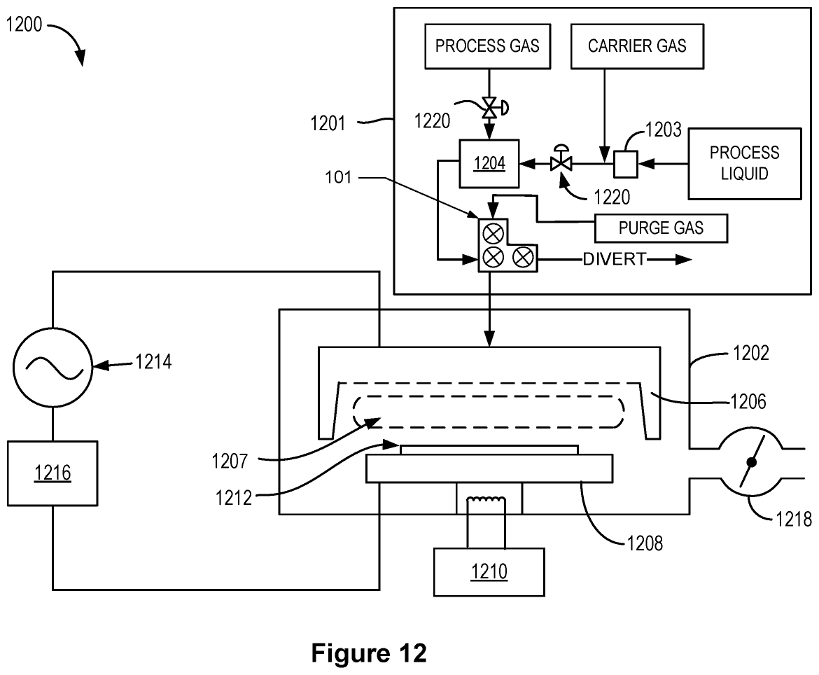

FIG. 12 schematically shows an embodiment of a process station 1200 that may be used to deposit material using atomic layer deposition (ALD) and/or chemical vapor deposition (CVD), either of which may be plasma enhanced. For simplicity, the process station 1200 is depicted as a standalone process station having a process chamber body 1202 for maintaining a low-pressure environment. However, it will be appreciated that a plurality of process stations 1200 may be included in a common process tool environment. Further, it will be appreciated that, in some embodiments, one or more hardware parameters of process station 1200, including those discussed in detail below, may be adjusted programmatically by one or more computer controllers.

Process station 1200 fluidly communicates with gas delivery system 1201 for delivering process gases to a distribution showerhead 1206. Gas delivery system 1201 includes a mixing vessel 1204 for blending and/or conditioning process gases for delivery to showerhead 1206. One or more mixing vessel inlet valves 1220 may control introduction of process gases to mixing vessel 1204.

The gas delivery system 1201 also includes the apparatus 101 provided above that includes the valve manifold, first, second, and third valves, and other features described herein. The manifold outlet of this apparatus 101 is seen fluidically connected to the showerhead 1206, the process gas is seen fluidically connected to the process gas inlet, the purge gas is fluidically connected to the purge gas inlet, and the divert outlet is fluidically connected to the divert flowpath as described herein. The purge gas and process gas are configured to flow to the showerhead 1206, and be controlled, as described herein.

Some reactants, like BTBAS, may be stored in liquid form prior to vaporization at and subsequent delivery to the process station. For example, the embodiment of FIG. 12 includes a vaporization point 1203 for vaporizing liquid reactant to be supplied to mixing vessel 1204. In some embodiments, vaporization point 1203 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 1203 may be heat traced. In some examples, mixing vessel 1204 may also be heat traced. In one non-limiting example, piping downstream of vaporization point 1203 has an increasing temperature profile extending from approximately 100° C. to approximately 150° C. at mixing vessel 1204.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 1203. In one scenario, a liquid injector may be mounted directly to mixing vessel 1204. In another scenario, a liquid injector may be mounted directly to showerhead 1206.

In some embodiments, a liquid flow controller upstream of vaporization point 1203 may be provided for controlling a mass flow of liquid for vaporization and delivery to process station 1200. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 1206 distributes process gases toward substrate 1212. In the embodiment shown in FIG. 12, substrate 1212 is located beneath showerhead 1206, and is shown resting on a pedestal 1208. It will be appreciated that showerhead 1206 may have any suitable shape, and may have any suitable number and arrangement of ports for distributing processes gases to substrate 1212.

In some embodiments, a microvolume 1207 is located beneath showerhead 1206. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 1208 may be raised or lowered to expose substrate 1212 to microvolume 1207 and/or to vary a volume of microvolume 1207. For example, in a substrate transfer phase, pedestal 1208 may be lowered to allow substrate 1212 to be loaded onto pedestal 1208. During a deposition process phase, pedestal 1208 may be raised to position substrate 1212 within microvolume 1207. In some embodiments, microvolume 1207 may completely enclose substrate 1212 as well as a portion of pedestal 1208 to create a region of high flow impedance during a deposition process.

Optionally, pedestal 1208 may be lowered and/or raised during portions the deposition process to modulate process pressure, reactant concentration, etc., within microvolume 1207. In one scenario where process chamber body 1202 remains at a base pressure during the deposition process, lowering pedestal 1208 may allow microvolume 1207 to be more efficiently evacuated. Example ratios of microvolume to process chamber volume include, but are not limited to, volume ratios between 1:1200 and 1:10. It will be appreciated that, in some embodiments, pedestal height may be adjusted programmatically by a suitable computer controller.

In another scenario, adjusting a height of pedestal 1208 may allow a plasma density to be varied during plasma activation and/or treatment cycles included in the deposition process. At the conclusion of the deposition process phase, pedestal 1208 may be lowered during another substrate transfer phase to allow removal of substrate 1212 from pedestal 1208.

While the example microvolume variations described herein refer to a height-adjustable pedestal, it will be appreciated that, in some embodiments, a position of showerhead 1206 may be adjusted relative to pedestal 1208 to vary a volume of microvolume 1207. Further, it will be appreciated that a vertical position of pedestal 1208 and/or showerhead 1206 may be varied by any suitable mechanism within the scope of the present disclosure. In some embodiments, pedestal 1208 may include a rotational axis for rotating an orientation of substrate 1212. It will be appreciated that, in some embodiments, one or more of these example adjustments may be performed programmatically by one or more suitable computer controllers.

Returning to the embodiment shown in FIG. 12, showerhead 1206 and pedestal 1208 electrically communicate with RF power supply 1214 and matching network 1216 for powering a plasma. In some embodiments, the plasma energy may be controlled by controlling one or more of a process station pressure, a gas concentration, an RF source power, an RF source frequency, and a plasma power pulse timing. For example, RF power supply 1214 and matching network 1216 may be operated at any suitable power to form a plasma having a desired composition of radical species. Examples of suitable powers are included above. Likewise, RF power supply 1214 may provide RF power of any suitable frequency. In some embodiments, RF power supply 1214 may be configured to control high- and low-frequency RF power sources independently of one another. Example low-frequency RF frequencies may include, but are not limited to, frequencies between 50 kHz and 1200 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 1208 may be temperature controlled via heater 1210. Further, in some embodiments, pressure control for deposition process station 1200 may be provided by butterfly valve 1218. As shown in the embodiment of FIG. 12, butterfly valve 1218 throttles a vacuum provided by a downstream vacuum pump (not shown). However, in some embodiments, pressure control of process station 1200 may also be adjusted by varying a flow rate of one or more gases introduced to process station 1200.

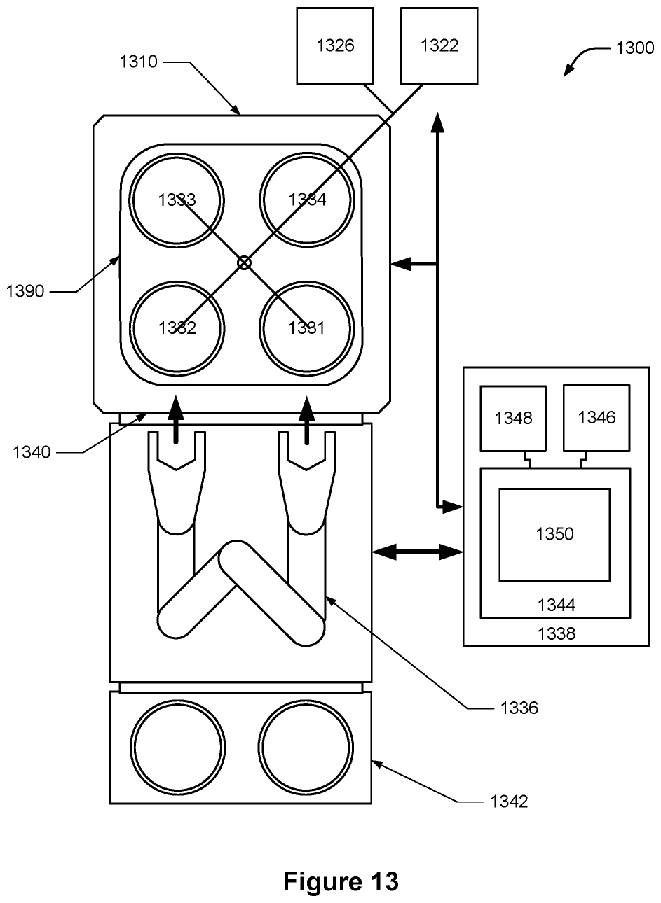

As described above, two or more process stations may be included in a multi-station substrate processing tool. FIG. 13 depicts an example multi-station substrate processing apparatus. Various efficiencies may be achieved through the use of a multi-station processing apparatus like that shown in FIG. 13 with respect to equipment cost, operational expenses, as well as increased throughput. For instance, a single vacuum pump may be used to create a single high-vacuum environment for all four process stations by evacuating spent process gases, etc. for all four process stations. Depending on the implementation, each process station may have its own dedicated showerhead for gas delivery, but may share the same gas delivery system. Likewise, certain elements of the plasma generator equipment may be shared amongst process stations (e.g., power supplies), although depending on the implementation, certain aspects may be process station-specific (for example, if showerheads are used to apply plasma-generating electrical potentials). Once again, it is to be understood that such efficiencies may also be achieved to a greater or lesser extent by using more or fewer numbers of process stations per processing chamber such as 2, 3, 5, 6, 7, 8, 9, 10, 11, 12, 13, 14, 15, or 16, or more process stations per reaction chamber.

The substrate processing apparatus 1300 of FIG. 13 employs a single substrate processing chamber 1310 that contains multiple substrate process stations, each of which may be used to perform processing operations on a substrate held in a wafer holder, e.g., a pedestal, at that process station. In this particular implementation, the multi-station substrate processing apparatus 1300 is shown having four process stations 1331, 1332, 1333, and 1334. Other similar multi-station processing apparatuses may have more or fewer processing stations depending on the implementation and, for instance, the desired level of parallel wafer processing, size/space constraints, cost constraints, etc. Also shown in FIG. 13 are a substrate handler robot 1336 and a controller 1338.

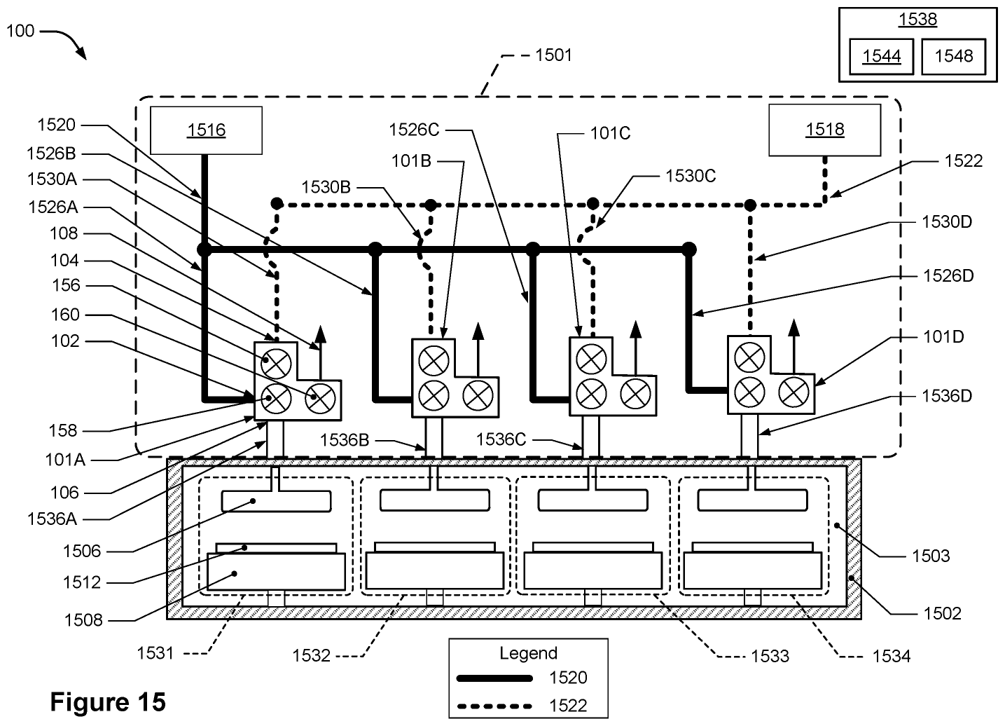

Although not shown in FIG. 13, it will be understood that each process station 1331, 1332, 1333, and 1334 may have its own valve manifold 100 and apparatus 101 as provided herein and shown in FIGS. 1-7C, for instance. For example, process station 1331 may have a first apparatus 101 with a valve manifold 100 fluidically connected to the showerhead of that process station 1331 and configured to control the process gas and purge gas flowed to that process station 1331, and process station 1332 may have a second apparatus 101 with a valve manifold 100 fluidically connected to the showerhead of that process station 1332 and configured to control the process gas and purge gas flowed to that process station 1332; the other process stations may be similarly configured. Additional examples of this are also seen in FIG. 15 and described below.

As shown in FIG. 13, the multi-station processing tool 1300 has a substrate loading port 1340, and a robot 1336 configured to move substrates from a cassette loaded through a pod 1342 through atmospheric port 1340, into the processing chamber 1310, and onto one of the four stations 1331, 1332, 1333, or 1334.

The RF power is generated at an RF power system 1322 and distributed to each of the stations 1331, 1332, 1333, or 1334; similarly a DC power source 1326 is distributed to each of the station. The RF power system may include one or more RF power sources, e.g., a high frequency (HFRF) and a low frequency (LFRF) source, impedance matching modules, and filters. In certain implementations, the power source may be limited to only the high frequency or low frequency source. The distribution system of the RF power system may be symmetric about the reactor and may have high impedance. This symmetry and impedance result in approximately equal amounts of power being delivered to each station.

FIG. 13 also depicts an implementation of a substrate transferring device 1390 for transferring substrates between process stations 1331, 1332, 1333, and 1334 within processing chamber 1314. It will be appreciated that any suitable substrate transferring device may be employed. Non-limiting examples include wafer carousels and wafer handling robots.

FIG. 13 also depicts an implementation of a system controller 1338 employed to control process conditions and hardware states of process tool 1300 and its process stations. System controller 1338 may include one or more memory devices 1344, one or more mass storage devices 1346, and one or more processors 1348. Processor 1348 may include one or more CPUs, ASICs, general-purpose computer(s) and/or specific purpose computer(s), one or more analog and/or digital input/output connection(s), one or more stepper motor controller board(s), etc.

In some implementations, the controller 1338 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1338, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controllers provided herein are configured to perform any of the techniques or processes provided herein, including having program instructions for executing any and all of the example techniques described herein. For example, a controller may be configured to cause a process gas to flow from a process gas supply through a process gas manifold towards the valve manifold, cause the first valve of the valve manifold to be in a closed state, and cause the second valve of the valve manifold to be in an open state to allow the process gas to flow to the showerhead and corresponding wafer, as illustrated in FIG. 7C, for example. The controller may also be configured to cause a purge gas to flow from a purge gas supply through a purge gas manifold towards the valve manifold, cause the first valve of the valve manifold to be in an open state, and cause the second valve of the valve manifold to be in a closed state to allow the purge gas to flow to the showerhead and corresponding wafer, as illustrated in FIGS. 7A and 7B, for example. In some instances, the controller may further be configured to cause the third valve of the valve manifold to be in an open state to allow the process gas to flow through the second valve and to the divert outlet of the valve manifold, such as shown in FIG. 7A for example.

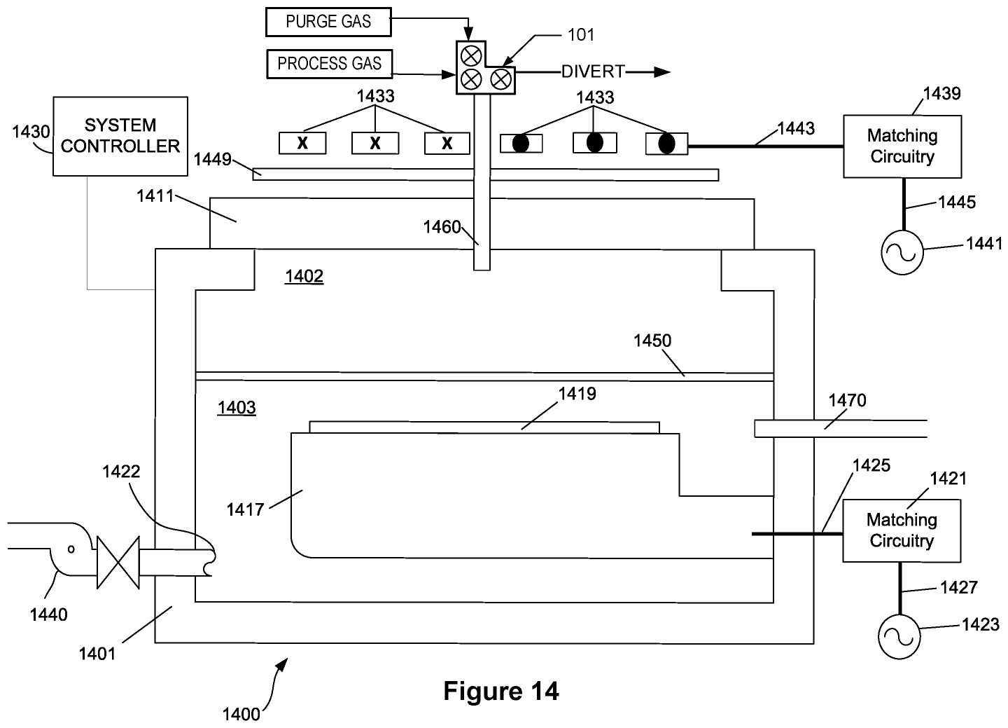

FIG. 14 schematically shows a cross-sectional view of an inductively coupled plasma etching apparatus 1400 in accordance with certain embodiments herein. A Kiyo™ reactor, produced by Lam Research Corp. of Fremont, CA, is an example of a suitable reactor that may be used to implement the techniques described herein. The inductively coupled plasma etching apparatus 1400 includes an overall etching chamber structurally defined by chamber walls 1401 and a window 1411. The chamber walls 1401 may be fabricated from stainless steel or aluminum. The window 1411 may be fabricated from quartz or other dielectric material. An optional internal plasma grid 1450 divides the overall etching chamber into an upper sub-chamber 1402 and a lower sub-chamber 1403. The plasma grid 1450 may include a single grid or multiple individual grids. In many embodiments, plasma grid 1450 may be removed, thereby utilizing a chamber space made of sub-chambers 1402 and 1403.

A chuck 1417 is positioned within the lower sub-chamber 1403 near the bottom inner surface. The chuck 1417 is configured to receive and hold a semiconductor wafer 1419 upon which the etching process is performed. The chuck 1417 can be an electrostatic chuck for supporting the wafer 1419 when present. In some embodiments, an edge ring (not shown) surrounds chuck 1417, and has an upper surface that is approximately planar with a top surface of a wafer 1419, when present over chuck 1417. The chuck 1417 also includes electrostatic electrodes for chucking and dechucking the wafer. A filter and DC clamp power supply (not shown) may be provided for this purpose. Other control systems for lifting the wafer 1419 off the chuck 1417 can also be provided. The chuck 1417 can be electrically charged using an RF power supply 1423. The RF power supply 1423 is connected to matching circuitry 1421 through a connection 1427. The matching circuitry 1421 is connected to the chuck 1417 through a connection 1425. In this manner, the RF power supply 1423 is connected to the chuck 1417.

A coil 1433 is positioned above window 1411. The coil 1433 is fabricated from an electrically conductive material and includes at least one complete turn. The exemplary coil 1433 shown in FIG. 14 includes three turns. The cross-sections of coil 1433 are shown with symbols, and coils having an “X” extend rotationally into the page, while coils having a “*” extend rotationally out of the page. An RF power supply 1441 is configured to supply RF power to the coil 1433. In general, the RF power supply 1441 is connected to matching circuitry 1439 through a connection 1445. The matching circuitry 1439 is connected to the coil 1433 through a connection 1443. In this manner, the RF power supply 1441 is connected to the coil 1433. An optional Faraday shield 1449 is positioned between the coil 1433 and the window 1411. The Faraday shield 1449 is maintained in a spaced apart relationship relative to the coil 1433. The Faraday shield 1449 is disposed immediately above the window 1411. The coil 1433, the Faraday shield 1449, and the window 1411 are each configured to be substantially parallel to one another. The Faraday shield may prevent metal or other species from depositing on the dielectric window of the plasma chamber.

Process gases may be supplied through a main injection port 1460 positioned in the upper chamber and/or through a side injection port 1470, sometimes referred to as an STG. A vacuum pump, e.g., a one or two stage mechanical dry pump and/or turbomolecular pump 1440, may be used to draw process gases out of the process chamber and to maintain a pressure within the process chamber 1400 by using a closed-loop-controlled flow restriction device, such as a throttle valve (not shown) or a pendulum valve (not shown), during operational plasma processing.

The apparatus 1400 may therefore include a gas delivery system that a process gas source, a purge gas source, a divert and the apparatus 101 provided above that includes the valve manifold, first, second, and third valves, and other features described herein. The manifold outlet of this apparatus 101 is seen fluidically connected to the main injection port 1460, the process gas is seen fluidically connected to the process gas inlet, the purge gas is fluidically connected to the purge gas inlet, and the divert outlet is fluidically connected to the divert flowpath as described herein. The purge gas and process gas are configured to flow to the main injection port 1460, and be controlled, as described herein.

During operation of the apparatus, one or more reactant gases may be supplied through injection ports 1460 and/or 1470. In certain embodiments, gas may be supplied only through the main injection port 1460, or only through the side injection port 1470. In some cases, the injection ports may be replaced by showerheads. The Faraday shield 1449 and/or optional grid 1450 may include internal channels and holes that allow delivery of process gases to the chamber. Either or both of Faraday shield 1449 and optional grid 1450 may serve as a showerhead for delivery of process gases.

Radio frequency power is supplied from the RF power supply 1441 to the coil 1433 to cause an RF current to flow through the coil 1433. The RF current flowing through the coil 1433 generates an electromagnetic field about the coil 1433. The electromagnetic field generates an inductive current within the upper sub-chamber 1402. The physical and chemical interactions of various generated ions and radicals with the wafer 1419 selectively etch features of the wafer.

If the plasma grid 1450 is used such that there is both an upper sub-chamber 1402 and a lower sub-chamber 1403, the inductive current acts on the gas present in the upper sub-chamber 1402 to generate an electron-ion plasma in the upper sub-chamber 1402. The optional internal plasma grid 1450, if present, may act to limit the number of hot electrons in the lower sub-chamber 1403. In some embodiments, the apparatus is designed and operated such that the plasma present in the lower sub-chamber 1403 is an ion-ion plasma. In other embodiments, the apparatus may be designed and operated such that the plasma present in the lower sub-chamber 1403 is an electron-ion plasma. Internal plasma grids and ion-ion plasma are further discussed in U.S. patent application Ser. No. 14/082,009, filed Nov. 15, 2013, and titled “INTERNAL PLASMA GRID FOR SEMICONDUCTOR FABRICATION,” and in U.S. Pat. No. 9,245,761, each of which is herein incorporated by reference in its entirety.

Volatile etching byproducts may be removed from the lower-sub chamber 1403 through port 1422. The chuck 1417 disclosed herein may operate at elevated temperatures ranging between about 30° C. and about 250° C. In some cases, the chuck 1417 may also operate at lower temperatures, for example when the chuck 1417 is actively chilled. In such cases the chuck 1417 may operate at substantially lower temperatures, as desired. The temperature will depend on the etching process operation and specific recipe. In some embodiments, the chamber 1401 may operate at pressures in the range of between about 1 mTorr and about 95 mTorr. In certain embodiments, the pressure may be higher.

Chamber 1401 may be coupled to facilities (not shown) when installed in a clean room or a fabrication facility. Facilities include plumbing that provide processing gases, vacuum, temperature control, and environmental particle control. These facilities are coupled to chamber 1401, when installed in the target fabrication facility. Additionally, chamber 1401 may be coupled to a transfer chamber that allows robotics to transfer semiconductor wafers into and out of chamber 1401 using typical automation.

In some embodiments, a system controller 1430 (which may include one or more physical or logical controllers) controls some or all of the operations of an etching chamber. The system controller 1430 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the system controller 1430 or they may be provided over a network. In certain embodiments, the system controller 1430 executes system control software.

In some cases, the system controller 1430 controls gas concentration, wafer movement, and/or the power supplied to the coils 1433 and/or electrostatic chuck 1417. The system controller 1430 may control the gas concentration by, for example, opening and closing relevant valves to produce one or more inlet gas stream that provide the necessary reactant(s) at the proper concentration(s). The wafer movement may be controlled by, for example, directing a wafer positioning system to move as desired. The power supplied to the coils 1433 and/or chuck 1417 may be controlled to provide particular RF power levels. Similarly, if the internal grid 1450 is used, any RF power applied to the grid may be adjusted by the system controller 1430.

The system controller 1430 may control these and other aspects based on sensor output (e.g., when power, potential, pressure, etc. reach a certain threshold), the timing of an operation (e.g., opening valves at certain times in a process), or based on received instructions from the user.

FIG. 15 depicts another substrate processing apparatus. The apparatus 1500 is a multi-station processing chamber 1502 with four processing stations 1531-1534, similar to FIG. 13, that are each encompassed by a dotted rectangle. The processing chamber 1502 has a top, bottom, and sidewalls that at least define a chamber interior 1503 in which the stations 1531-1534 are positioned. Each station includes a pedestal 1508, a substrate 1512 on the pedestal 1508, and a showerhead 1506; these items are labeled in processing station 1531. This apparatus 1500 may be used for deposition, etching, or both.

The multi-station tool 1500 also includes a fluid delivery system 1501, similar to FIG. 12, encompassed within the dashed rectangle and fluidically coupled to each processing station 1531-1534 for delivering gases to the showerheads 1510. The fluid delivery system 1501 includes a process gas source 1516 and a purge gas source 1518 (similar to FIG. 12), and a plurality of manifolds for delivering these gases to each processing station 1531-1534. Although not depicted, the fluid delivery system 1501 may include other features such as additional fluid sources, such as at least three, four, six, eight, ten, or twenty fluid sources, one or more mixing vessels, vaporization points for vaporizing liquid reactant to be supplied to a mixing vessel, as well as various valves, manifolds, heaters, and gas lines to direct and control the flow of fluids throughout the fluid delivery system 1501. The showerhead 1506 distributes gases and/or reactants (e.g., film precursors, purge gases) toward the substrate 1512 at the corresponding processing station.

In FIG. 15, the fluid delivery system 1501 is illustrated with two manifolds, a first manifold 1520, depicted with a heavy solid line, and a second manifold 1522, depicted with a heavy dotted line as indicated by the Figure Legend. The first manifold 1520 includes a plurality of legs 1526A-D that are each fluidically connected to one corresponding station 1531-1534, respectively. In some implementations, the first manifold 1520 may have multiple divisions and splits (not shown) which result in the first manifold 1520 having four individual legs 1526A-D that each terminate at a different, corresponding station 1531-1534, respectively. The second manifold 1522 in FIG. 15 includes a plurality of legs 1530A-D that are each fluidically connected to one corresponding station 1531-1534, respectively. In some implementations, the second manifold 1522 may have multiple divisions and splits (not shown) which result in the second manifold 1520 having four individual legs 1530A-D that each terminate at a different, corresponding station 1531-1534, respectively.

Each station in FIG. 15 also includes a corresponding apparatus 101A-D with valve manifold 100 and three valves as provided herein. Apparatuses 101A-D are the same apparatus as shown in FIGS. 5-7C and 12; apparatus 101A includes additional labels, such as the first valve 156, the second valve 158, the third valve 160, the process gas inlet 102, the purge gas inlet 104, the manifold outlet 106, and the divert outlet 108. The manifold outlet 106 of each valve manifold 100 is fluidically connected to a corresponding station inlet 1536A-D, respectively, of each station 1531-1534. Each station inlet 1536A-D is fluidically connected to the showerhead of the corresponding station 1531-1534, respectively, such that fluid flows to the showerhead of a station through that station's inlet. For example, fluid may flow through station inlet 1536A to showerhead 1506 of station 1531. The process gas supply 1516 is therefore fluidically connected to each process gas inlet of each valve manifold 100 of each apparatus 101A-D via the process gas manifold 1520. The purge gas supply 1518 is also fluidically connected to each purge gas inlet of each valve manifold 100 of each apparatus 101A-D via the purge gas manifold 1522.

The apparatus 1500 also includes a controller 1538 with one or more memories 1544 and one or more processors 1544 as provided herein. This controller 1538 is configured to control the operation of the apparatus 1500, including causing process gas to flow from the process gas source 1516 to each apparatus 101A-D and corresponding processing station 1531-1534, causing purge gas to flow from the process gas source 1518 to each apparatus 101A-D and corresponding processing station 1531-1534, the operation of each valve on the apparatus 101A-D, as well as to perform any of the techniques provide herein.

It is to be understood that the use of ordinal indicators, e.g., (a), (b), (c), . . . , herein is for organizational purposes only, and is not intended to convey any particular sequence or importance to the items associated with each ordinal indicator. For example, “(a) obtain information regarding velocity and (b) obtain information regarding position” would be inclusive of obtaining information regarding position before obtaining information regarding velocity, obtaining information regarding velocity before obtaining information regarding position, and obtaining information regarding position simultaneously with obtaining information regarding velocity. There may nonetheless be instances in which some items associated with ordinal indicators may inherently require a particular sequence, e.g., “(a) obtain information regarding velocity, (b) determine a first acceleration based on the information regarding velocity, and (c) obtain information regarding position”; in this example, (a) would need to be performed (b) since (b) relies on information obtained in (a)-(c), however, could be performed before or after either of (a) or (b).

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A valve manifold for use in a semiconductor processing tool, comprising:
a manifold body;
a purge gas inlet;
a process gas inlet;
a manifold outlet;
a divert outlet;
a first valve interface;
a second valve interface; and
a third valve interface, wherein:
the first valve interface and the third valve interface each include a first port, and a second port,
the second valve interface includes a first port, a second port, a third port, and a fourth port,
the first port of the first valve interface is fluidically connected with the purge gas inlet via a first flowpath internal to the manifold body and having no dead legs,
the second port of the first valve interface is fluidically connected with the second port of the second valve interface via a second flowpath internal to the manifold body and having no dead legs,
the first port of the second valve interface is fluidically connected with the process gas inlet via a third flowpath internal to the manifold body and having no dead legs,
the third port of the second valve interface is fluidically connected with the first port of the third valve interface via a fourth flowpath internal to the manifold body and having no dead legs,
the fourth port of the second valve interface is fluidically connected with the manifold outlet via a fifth flowpath internal to the manifold body and having no dead legs, and
the second port of the third valve interface is fluidically connected with the divert outlet via a sixth flowpath internal to the manifold body and having no dead legs.

2. The valve manifold of claim 1, wherein:
the purge gas inlet is configured to connect to a purge gas supply, and
the process gas inlet is configured to connect to a process gas supply.

3. The valve manifold of claim 1, wherein:
the manifold outlet is located on a first side of the manifold body, and
the first valve interface is located on a second side of the manifold body different from the first side.

4. The valve manifold of claim 3, wherein the second valve interface and the third valve interface are located on the second side of the manifold body.

5. The valve manifold of claim 3, wherein:
the second valve interface is located on a third side of the manifold body, and
the third valve interface is located on a fourth side of the manifold body.

6. The valve manifold of claim 3, wherein:
the purge gas inlet is located on a third side of the manifold body, and
the process gas inlet is located on a fourth side of the manifold body.

7. The valve manifold of claim 6, wherein the manifold outlet is located on a fifth side of the manifold body.

8. The valve manifold of claim 6, wherein the first side and the third side are substantially parallel to each other.

9. The valve manifold of claim 6, wherein the first side, the third side, and the fourth side are substantially orthogonal to the second side.

10. The valve manifold of claim 1, wherein the manifold body has an L-shape.

11. An apparatus for delivery of a purge gas and a first process gas to a semiconductor processing tool, the apparatus comprising:
the valve manifold claim 1;
a first valve;
a second valve; and
a third valve, wherein:
the first valve is configured to be switchable between an open state and a closed state, and is interfaced with the first valve interface,
the second valve is configured to be switchable between an open state and a closed state, and is interfaced with the second valve interface,
the third valve is configured to be switchable between an open state and a closed state, and is interfaced with the third valve interface,
when the second valve is the open state, the first port of the second valve interface is fluidically connected to the fourth port of the second valve interface and not fluidically connected to the third port of the second valve interface,
when the second valve is the closed state, the first port of the second valve interface is fluidically connected to the third port of the second valve interface and to the first port of the third valve interface, and not fluidically connected to the first port of the second valve interface,
when the second valve is in the open state or the closed state, the second port of the second valve interface is fluidically connected to the fourth port of the second valve interface,
when the first valve is in the open state, the purge gas inlet and the second port of the first valve interface are fluidically connected to the fourth port of the second valve interface and to the manifold outlet, and
when the first valve is in the closed state, the purge gas inlet and the first port of the first valve interface are not fluidically connected to the fourth port of the second valve interface or to the manifold outlet.

12. The apparatus of claim 11, wherein when the first valve is in the closed state and the second valve is concurrently in the open state, the process gas inlet is fluidically connected to the manifold outlet and not fluidically connected to the purge gas inlet.

13. The apparatus of claim 12, wherein when the first valve is in the closed state and the second valve is concurrently in the open state, a process gas is configured to flow from the process gas inlet to the manifold outlet by flowing, at least in part, from the purge gas inlet through the third flowpath, through the first port of the second valve interface, through the fourth port, through the fifth flowpath, and to the manifold outlet.

14. The apparatus of claim 11, wherein when the first valve is in the open state and the second valve is concurrently in the closed state, the purge gas inlet is fluidically connected to the manifold outlet and not fluidically connected to the process gas inlet.

15. The apparatus of claim 14, wherein when the second valve is in the closed state and the third valve is concurrently in the open state, the process gas inlet is fluidically connected to the divert outlet and not fluidically connected to the manifold outlet.

16. The apparatus of claim 15, wherein when the second valve is in the closed state and the third valve is concurrently in the open state, a process gas is configured to flow from the process gas inlet to the divert outlet by flowing from the purge gas inlet through the third flowpath, through the first port of the second valve interface, through the third port, through the fourth flowpath, through the first port of the third valve interface, through the second port of the first valve interface, through the sixth flowpath, and to the divert outlet.

17. The apparatus of claim 14, wherein when the second valve is in the closed state and the third valve is concurrently in the closed state, the process gas inlet is not fluidically connected to the divert outlet and not fluidically connected to the manifold outlet.

18. The apparatus of claim 14, wherein when the first valve is in the open state and the second valve is concurrently in the closed state, a purge gas is configured to flow from the purge gas inlet to the manifold outlet by flowing, at least in part, from the first flowpath through the first port of the first valve interface, through the second port of the first valve interface, through the second flowpath, through the second port of the second valve interface, through the fourth port, through the fifth flowpath, and through the manifold outlet.

19. The apparatus of claim 11, further comprising:
a purge gas supply;
a process gas supply; and
a controller having one or more processors and one or more memories, and communicatively connected to the purge gas supply, the process gas supply, the first valve, the second valve, and the third valve, wherein the one or more memories store instructions that are configured to:
cause the first valve to be in the closed state and the second valve to be concurrently in the open state,
cause, while the first valve is in the closed state and the second valve is concurrently in the open state, the process gas to flow to the process gas inlet and thereby cause the process gas to flow through the manifold outlet and not to flow to the purge gas inlet, cause the first valve to be in the open state and the second valve to be concurrently in the closed state, and
cause, while the first valve is in the open state and the second valve is concurrently in the closed state, the purge gas to flow to the purge gas inlet and thereby cause the purge gas to flow to the manifold outlet.

20. The apparatus of claim 19, wherein the one or more memories store further instructions that are configured to:
cause, while the first valve is in the open state and the second valve is concurrently in the closed state, the third valve to be in the open state and thereby cause the process gas to flow to the divert outlet.

21. The apparatus of claim 19, further comprising a purge gas manifold forming a fluidic connection between purge gas sources and the purge gas inlet, wherein the one or more memories store further instructions that are configured to:
cause, while the first valve is in the closed state, the purge gas to flow to the purge gas inlet and thereby charge the purge gas manifold with the purge gas.

22. A method comprising:
flowing a process gas from a process gas source to the process gas inlet of the valve manifold of the apparatus of claim 11 while the first valve is in the closed state and the second valve is in the open state thereby causing the process gas to flow to a showerhead fluidically connected to the manifold outlet;
flowing a purge gas from a purge gas source to the purge gas inlet of the valve manifold of the apparatus of claim 11 while the first valve is in the open state and the second valve is in the closed state thereby causing the purge gas to flow to the showerhead fluidically connected to the manifold outlet; and
flowing, while the first valve is in the open state and the second valve is in the closed state, the process gas to the process gas inlet while the third valve is in the open state thereby causing the process gas to flow to the divert outlet.

23. The method of claim 22, wherein:
the showerhead is a part of a processing station in a processing chamber,
the process gas comprises a precursor for depositing a material onto a wafer in the processing station,
the flowing the process gas through the manifold outlet thereby causes the process gas to flow onto the wafer and the precursor to adsorb onto the wafer,
the flowing the purge gas through the manifold outlet is performed after the flowing the process gas through the manifold outlet, and
the flowing the process gas through the divert outlet occurs concurrently with the flowing the purge gas through the manifold outlet.

24. The method of claim 23, further comprising activating the adsorbed precursor on the wafer, wherein:
the activating occurs after the flowing the process gas through the manifold outlet and the flowing the purge gas through the manifold outlet, and
the flowing the purge gas through the manifold outlet is repeated after the activating.

25. The method of claim 22, wherein:
the showerhead is a part of a processing station in a processing chamber,
the process gas comprises a modifying molecule for modifying a layer of material onto a wafer in the processing station,
the flowing the process gas through the manifold outlet thereby causes the process gas to flow onto the wafer and the modifying molecule to modify the layer of material to form a modified layer of material on the wafer,
the flowing the purge gas through the manifold outlet is performed after the flowing the process gas through the manifold outlet, and
the flowing the process gas through the divert outlet occurs concurrently with the flowing the purge gas through the manifold outlet.

26. The method of claim 25, further comprising removing the modified layer of material from the wafer, wherein:
the removing occurs after the flowing the process gas through the manifold outlet and the flowing the purge gas through the manifold outlet, and
the flowing the purge gas through the manifold outlet is repeated after the removing.
